(19) United States
(12) Patent Application Publication
(10) Pub. No.: US 2019/0318918 A1
(43) Pub. Date: Oct. 17, 2019

(54) PLASMA PROCESSING APPARATUS, PLASMA CONTROL METHOD, AND COMPUTER STORAGE MEDIUM

(71) Applicant: TOKYO ELECTRON LIMITED, Tokyo (JP)

(72) Inventors: Yusuke SAITOH, Miyagi (JP); Tokuhisa OIWA, Tokyo (JP)

(73) Assignee: TOKYO ELECTRON LIMITED, Tokyo (JP)

(21) Appl. No.: 16/381,424

(22) Filed: Apr. 11, 2019

(30) Foreign Application Priority Data
Apr. 11, 2018 (JP) 2018-076094

(51) Int. Cl. H01J 37/32

(52) U.S. Cl. CPC H01J 37/32642; H01J 37/32532; H01J 37/3244; H01J 37/32935

(57) ABSTRACT

A plasma processing apparatus includes a mounting table on which a target object as a plasma processing target is mounted, a focus ring disposed to surround the target object, and an acquisition unit configured to acquire state information indicating a measured state of the target object. The plasma processing apparatus further includes a plasma control unit configured to control plasma processing based on the state of the target object indicated by the state information acquired by the acquisition unit such that a difference between a height of an interface of a plasma sheath above the target object and a height of an interface of a plasma sheath above the focus ring is within a predetermined range.

### CROSS-REFERENCE TO RELATED APPLICATION

This application claims priority to Japanese Patent Application No. 2018-076094, filed on Apr. 11, 2018, the entire contents of which are incorporated herein by reference.

### TECHNICAL FIELD

The present disclosure relates to a plasma processing apparatus, a plasma control method, and a computer storage medium.

### BACKGROUND

Conventionally, there is known a plasma processing apparatus for performing plasma processing such as etching or the like on a target object such as a semiconductor wafer (hereinafter, also referred to as “wafer”) or the like by using plasma (See, e.g., Japanese Patent Application Publication Nos. 2016-146472 and 2002-176030). In the plasma processing apparatus, etching is performed by generating plasma in a processing space above the target object, accelerating ions in the plasma by a voltage applied to the plasma, and injecting the ions into the wafer.

### SUMMARY

In accordance with an aspect of the present disclosure, there is provided a plasma processing apparatus including: a mounting table on which a target object as a plasma processing target is mounted; a focus ring disposed to surround the target object; an acquisition unit configured to acquire state information indicating a measured state of the target object; and a plasma control unit configured to control plasma processing based on the state of the target object indicated by the state information acquired by the acquisition unit such that a difference between a height of an interface of a plasma sheath above the target object and a height of an interface of a plasma sheath above the focus ring is within a predetermined range.

### BRIEF DESCRIPTION OF THE DRAWINGS

The objects and features of the present disclosure will become apparent from the following description of embodiments, given in conjunction with the accompanying drawings, in which:

FIG. 1 is a schematic cross-sectional view showing an example of a schematic configuration of a plasma processing apparatus according to a first embodiment;

FIG. 2 is a block diagram showing an example of a schematic configuration of a control unit for controlling the plasma processing apparatus according to the first embodiment;

FIG. 3 shows wafer sizes;

FIG. 4 schematically shows an example of a state of a plasma sheath;

FIG. 5 schematically shows an ideal state of the plasma sheath;

FIG. 6 shows an example of the relation between an angle θ of an etched hole and a thickness of a focus ring;

FIGS. 7A to 7F schematically show states in which holes are etched;

FIG. 8A is a graph showing an example of the relation between a magnetic field strength and an electron density of plasma;

FIG. 8B is a graph showing an example of the relation between a magnetic field strength and a thickness of a plasma sheath;

FIG. 9 is a flowchart showing an example of a sequence of a plasma control process;

FIG. 10 is a schematic cross-sectional view showing an example of a schematic configuration of a plasma processing apparatus according to a second embodiment;

FIG. 11 is a schematic cross-sectional view showing an example of a schematic configuration of a plasma processing apparatus according to a third embodiment;

FIG. 12 is a schematic cross-sectional view showing an example of a schematic configuration of a plasma processing apparatus according to a fourth embodiment;

FIG. 13 is a schematic cross-sectional view showing configurations of main parts of a first mounting table and a second mounting table according to the fourth embodiment;

FIG. 14 is a top view of the first mounting table and the second mounting table according to the fourth embodiment which is viewed from the top;

FIG. 15 is a schematic cross-sectional view of configurations of main parts of a first mounting table and a second mounting table according to a fifth embodiment;

FIG. 16 shows an example of a reflection system of laser light;

FIG. 17 shows an example of a distribution of detected intensities of the light;

FIG. 18A shows an example of the relation between an etching rate and a thickness of a focus ring; and

FIG. 18B shows an example of the relation between an angle θ of an etched hole and a thickness of a focus ring.

### DETAILED DESCRIPTION

Hereinafter, embodiments of a plasma processing apparatus, a plasma control method, and a plasma control program of the present disclosure will be described in detail with reference to the accompanying drawings. The embodiments are not intended to limit the plasma processing apparatus, the plasma control method, and the plasma control program of the present disclosure. The embodiments may be appropriately combined without contradicting processing contents. In the following embodiments, a wafer will be described as an example of a target object. However, the target object is not limited to the wafer, and may also be a substrate, e.g., a glass substrate or the like.

Although a wafer size is determined based on a standard, the wafer state, e.g., diameter, thickness and the like may vary within the standard. Therefore, in the plasma processing apparatus, etching characteristics of wafers may vary due to variations of the wafer state. Particularly, a peripheral portion of the wafer is easily affected by variations of the wafer state.

Therefore, suppression of variations in the etching characteristics of wafers is desirable.

### First Embodiment

<Configuration of Plasma Processing Apparatus>

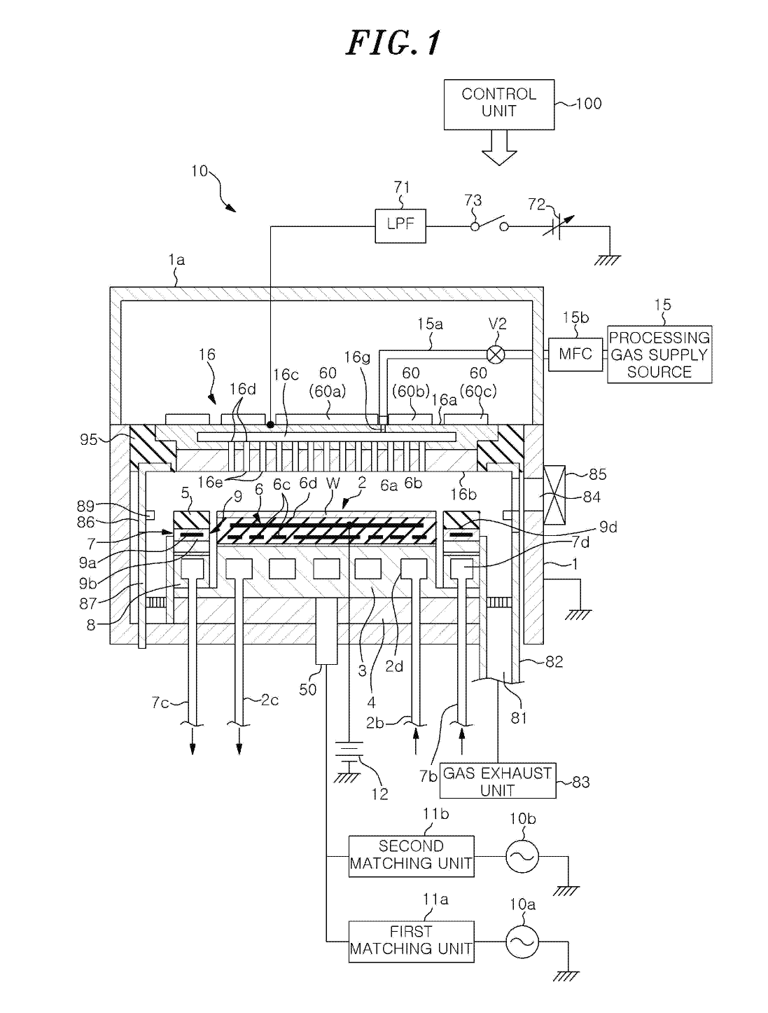

First, a schematic configuration of a plasma processing apparatus 10 according to a first embodiment will be described. FIG. 1 is a schematic cross-sectional view showing an example of the schematic configuration of the plasma processing apparatus according to the first embodiment. The plasma processing apparatus 10 includes an airtight processing chamber 1 that is electrically grounded. The processing chamber 1 is formed in a cylindrical shape and made of, e.g., aluminum having an anodically oxidized surface, or the like. The processing chamber 1 defines a processing space where plasma is generated. A first mounting table 2 for horizontally supporting a wafer W as a work-piece is provided in the processing chamber 1.

The first mounting table 2 has a substantially columnar shape with upper and lower surfaces directed vertically. The upper surface serves as a mounting surface 6d on which the wafer W is mounted. The mounting surface 6d of the first mounting table 2 has substantially the same size as that of the wafer W. The first mounting table 2 includes a base 3 and an electrostatic chuck 6.

The base 3 is made of a conductive metal, e.g., aluminum having an anodically oxidized surface, or the like. The base 3 serves as a lower electrode. The base 3 is supported by a supporting member 4 made of an insulator. The supporting member 4 is installed at a bottom portion of the processing chamber 1.

The electrostatic chuck 6 has a flat disc-shaped upper surface serving as the mounting surface 6d on which the wafer W is mounted. The electrostatic chuck 6 is provided at a center portion of the first mounting table 2 when seen from the top. The electrostatic chuck 6 includes an electrode 6a and an insulator 6b. The electrode 6a is embedded in the insulator 6b. A DC power supply 12 is connected to the electrode 6a. The wafer W is attracted and held on the electrostatic chuck 6 by a Coulomb force generated by applying a DC voltage from the DC power supply 12 to the electrode 6a. A heater 6c is provided in the insulator 6b of the electrostatic chuck 6. The heater 6c controls a temperature of the wafer W by a power supplied through a power supply mechanism (not shown).

A second mounting table 7 is provided around an outer peripheral surface of the first mounting table 2. The second mounting table 7 is formed in a cylindrical shape whose inner diameter is greater than an outer diameter of the first mounting table 2 by a predetermined value. The first mounting table 2 and the second mounting table 7 are coaxially arranged. The second mounting table 7 has an upper surface serving as a mounting surface 9d on which an annular focus ring 5 is mounted. The focus ring 5 is made of, e.g., single crystalline silicon, and mounted on the second mounting table 7.

The second mounting table 7 includes a base 8 and a focus ring heater unit 9. The base 8 is made of a conductive metal similar to that of the base 3. The base 8 is made of, e.g., aluminum having an anodically oxidized surface, or the like. A lower portion of the base 3 which faces the supporting member 4 is greater in a diametrical direction than an upper portion of the base 3 and extends in a flat plate shape to a position below the second mounting table 7. The base 8 is supported by the base 3. The focus ring heater unit 9 is supported by the base 8. The focus ring heater unit. 9 has an annular shape with a flat upper surface serving as a mounting surface 9d on which the focus ring 5 is mounted. The focus ring heater unit 9 includes a heater 9a and an insulator 9b. The heater 9a is embedded in the insulator 9b. A power is supplied to the heater 9a through a power supply mechanism (not shown) to control a temperature of the focus ring 5. In this manner, the temperature of the wafer W and the temperature of the focus ring 5 are independently controlled by different heaters.

A power feed rod 50 for supplying RF (Radio Frequency) power is connected to the base 3. The power feed rod 50 is connected to a first RF power supply 10a via a first matching unit 11a and connected to a second RF power supply 10b via a second matching unit 11b. The first RF power supply 10a generates power for plasma generation. A high frequency power having a predetermined frequency is supplied from the first RF power supply 10a to the base 3 of the first mounting table 2. The second RF power supply 10b generates power for ion attraction (bias). A high frequency power having a predetermined frequency lower than that from the first RF power supply 10a is supplied from the second RF power supply 10b to the base 3 of the first mounting table 2.

A coolant path 2d is formed in the base 3. The coolant path 2d has one end connected to a coolant inlet line 2b and the other end connected to a coolant outlet line 2c. A coolant path 7d is formed in the base 8. The coolant path 7d has one end connected to a coolant inlet line 7b and the other end connected to a coolant outlet line 7c. The coolant path 2d is positioned below the wafer W and absorbs heat of the wafer W. The coolant path 7d is positioned below the focus ring 5 and absorbs heat of the focus ring 5. In the plasma etching apparatus 10, temperatures of the first mounting table 2 and the second mounting table 7 can be individually controlled by circulating a coolant, e.g., cooling water or the like, through the coolant path 2d and the coolant path 7d, respectively. Further, the plasma etching apparatus 10 may be configured such that a cold heat transfer gas is supplied to a backside of the wafer W and to a bottom surface of the focus ring 5 to separately control the temperatures thereof. For example, a gas supply line for supplying a cold heat transfer gas (backside gas) such as He gas or the like to the backside of the wafer W may be provided to penetrate through the first mounting table 2 and the like. The gas supply line is connected to a gas supply source. With this configuration, the wafer W attracted and held by the electrostatic chuck 6 on the upper surface of the first mounting table 2 can be controlled to a predetermined temperature.

A shower head 16 serving as an upper electrode is provided above the first mounting table 2 to face the first mounting table 2 in parallel therewith. The shower head 16 and the first mounting table 2 function as a pair of electrodes (upper electrode and lower electrode).

The shower head 16 is provided at a ceiling wall portion of the processing chamber 1. The shower head 16 includes a main body 16a and a ceiling plate 16b serving as an electrode plate. The shower head 16 is supported at an upper portion of the processing chamber 1 through an insulating member 95. The main body 16a is made of a conductive material, e.g., aluminum having an anodically oxidized surface, or the like. The ceiling plate 16b is detachably held at a bottom portion of the main body 16a.

A gas diffusion space 16c is formed in the main body 16a. A plurality of gas holes 16d is formed in the bottom portion of the main body 16a to be downwardly extended from the gas diffusion space 16c. Gas injection holes 16e are formed through the ceiling plate 16b in a thickness direction thereof. The gas injection holes 16e communicate with the respective gas holes 16d. With this configuration, the processing gas supplied to the gas diffusion space 16c is distributed in a shower form into the processing chamber 1 through the gas holes 16d and the gas injection holes 16e.

A gas inlet port 16g for introducing the processing gas into the gas diffusion space 16c is formed in the main body 16a. One end of a gas supply line 15a is connected to the gas inlet port 16g and the other end of the gas supply line 15a is connected to a processing gas supply source 15 for supplying a processing gas. A mass flow controller (MFC) 15b and an opening/closing valve V2 are disposed in the gas supply line 15a in that order from an upstream side. The processing gas for plasma etching is supplied from the processing gas supply source 15 to the gas diffusion space 16c through the gas supply line 15a and distributed in a shower form into the processing chamber 1 through the gas holes 16d and the gas injection holes 16e.

A variable DC power supply 72 is electrically connected to the shower head 16 serving as the upper electrode via a low pass filter (LPF) 71. A power supply of the variable DC power supply 72 is on-off controlled by an on/off switch 73. Current/voltage of the variable DC power supply 72 and on/off of the on/off switch 73 are controlled by a control unit 100 to be described later. As will be described later, when plasma is generated in the processing space by applying the high frequency power from the first and the second RF power supply 10a and 10b to the first mounting table 2, the on/off switch 73 is turned on by the control unit 100 and a predetermined DC voltage is applied to the shower head 16 serving as the upper electrode, if necessary.

A plurality of electromagnets 60 is arranged on an upper surface of the shower head 16. In the present embodiment, three electromagnets 60a to 60c are arranged on the upper surface of the shower head 16. The electromagnet 60a is formed in a disc-shape and disposed above a central portion of the first mounting table 2. The electromagnet 60b is formed in an annular shape and disposed above a peripheral portion of the first mounting table 2 to surround the electromagnet 60a. The electromagnet 60c is formed in an annular shape greater than that of the electromagnet 60b and disposed above the second mounting table 7 to surround the electromagnet 60b.

Each of the electromagnets 60a to 60c is individually connected to a power supply (not shown), and generates a magnetic field by power supplied from the power supply. The power supplied from the power supply to the electromagnets 60a to 60c can be controlled by the control unit 100 to be described later. The control unit 100 controls the power supplied from the power supply to the electromagnets 60a to 60c, thereby controlling the magnetic field generated by the electromagnets 60a to 60c.

A cylindrical ground conductor 1a extends upward from a sidewall of the processing chamber 1 to a position higher than the shower head 16. The cylindrical ground conductor 1a has a ceiling wall at the top thereof.

A gas exhaust port 81 is formed at a bottom portion of the processing chamber 1. A gas exhaust unit 83 is connected to the gas exhaust port 81 through a gas exhaust line 82. The gas exhaust unit 83 has a vacuum pump. By operating the vacuum pump, a pressure in the processing chamber 1 can be decreased to a predetermined vacuum level. A loading/unloading port 84 for the wafer W is provided at a sidewall of the processing chamber 1. A gate valve 85 for opening/closing the loading/unloading port 84 is provided at the loading/unloading port 84.

A deposition shield 86 is provided along an inner surface of the sidewall of the processing chamber 1. The deposition shield 86 prevents etching by-products (deposits) from being attached to the inner surface of the processing chamber 1. A conductive member (GND block) 89 is provided at a portion of the deposition shield 86 at substantially the same height as the height of the wafer W. The conductive member 89 is connected such that a potential for the ground can be controlled. Due to the presence of the conductive member 89, abnormal discharge is prevented. A deposition shield 87 extending along the first mounting table 2 is provided at a lower end portion of the deposition shield 86. The deposition shields 86 and 87 are detachably provided.

The operation of the plasma processing apparatus 10 configured as described above is integrally controlled by the control unit 100. The control unit 100 is, e.g., a computer, and controls the respective components of the plasma processing apparatus 10.

<Configuration of Control Unit>

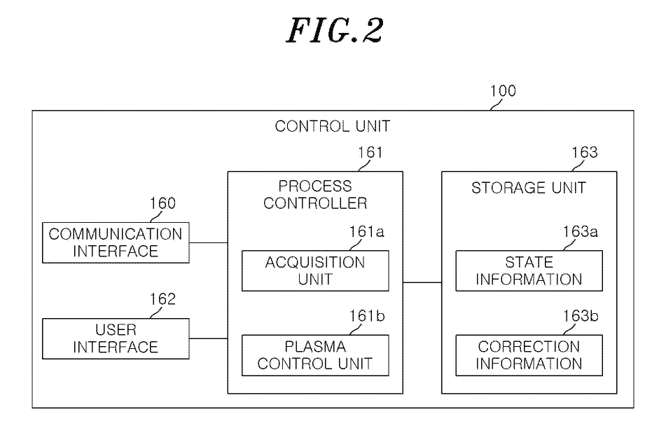

Next, the control unit 100 will be described in detail. FIG. 2 is a block diagram showing an example of a schematic configuration of the control unit for controlling the plasma processing apparatus according to the first embodiment. The control unit 100 includes a communication interface 160, a process controller 161, a user interface 162, and a storage unit 163.

The communication interface 160 can communicate with other devices via a network, and transmits and receives various data to and from other devices.

The process controller 161 has a CPU (Central Processing Unit) and controls the respective components of the plasma processing apparatus 10.

The user interface 162 includes a keyboard through which a process manager inputs commands to operate the plasma processing apparatus 10, a display for visualizing an operation status of the plasma processing apparatus 10, and the like.

The storage unit 163 stores therein recipes including a control program (software), processing condition data and the like for realizing various processes performed by the plasma processing apparatus 10 under the control of the process controller 161. For example, a control program for performing a plasma control process to be described later is stored in the storage unit 163. In addition, a state information 163a and a correction information 163b are stored in the storage unit 163. The recipes including the control program, the processing condition data and the like can be stored in a computer-readable storage medium (e.g., a hard disk, an optical disk such as DVD or the like, a flexible disk, a semiconductor memory, or the like) or can be transmitted, when needed, from another apparatus through, e.g., a dedicated line, and used on-line.

The state information 163a is data in which the state of the wafer W as a plasma processing target is stored. For example, the state information 163a includes a thickness of the wafer W. In a transfer system in which the wafer W transferred to the plasma processing apparatus 10, the state of the wafer W is measured in an apparatus before the wafer W is transferred to the plasma processing apparatus 10. For example the wafer W passes through an alignment apparatus before it is transferred to the plasma processing apparatus 10. The alignment apparatus is provided with a horizontal rotation stage and can control various alignment operations such as control of a rotation position of the wafer W and the like. The alignment apparatus measures the state of the wafer such as a thickness and an outer diameter of the wafer W. The state information including the state of the wafer such as the thickness and the outer diameter is stored as the state information 163a in the storage unit 163 via a network.

The correction information 163b is data in which various information for correcting the conditions of the plasma processing are stored. The correction information 163b will be described in detail later.

The process controller 161 has an internal memory for storing program or data, reads out the control program stored in storage unit 163, and executes processing of the read-out control program. The process controller 161 functions as various processing units by executing the control program. For example, the process controller 161 has functions of an acquisition unit 161a and a plasma control unit 161b. In the plasma processing apparatus 10 of the present embodiment, the case which the process controller 161 has the functions of the acquisition unit 161a and the plasma control unit 161b will be described as an example. However, the functions of the acquisition unit 161a and the plasma control unit 161b may be distributed to a plurality of controllers and realized.

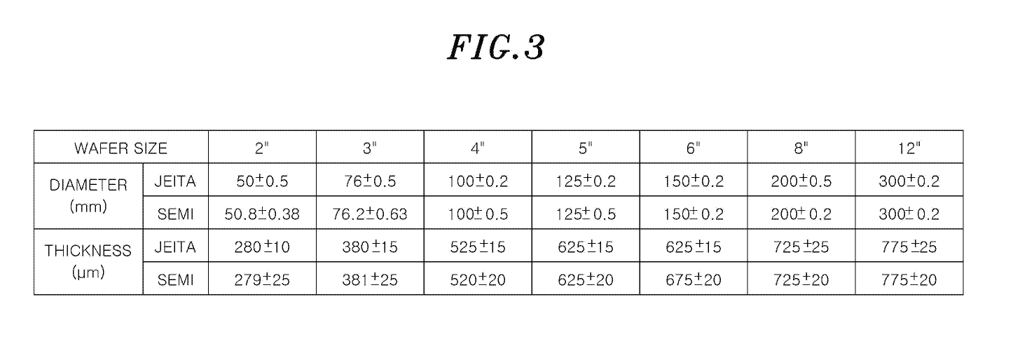

Although the size of the wafer W is determined based on the standard, a certain error is allowed. FIG. 3 shows wafer sizes. FIG. 3 shows the range of the diameter and the thickness for each wafer size according to the standards of JEITA (Japan Electronics and Information Technology Industries Association) and SEMI (Semiconductor Equipment and Materials International). As described above, the standard diameter and the standard thickness of the wafer W are determined for each wafer size, and the standard value may have a certain tolerance. Therefore, even if the wafer W is within the standard, the wafer state has an error in a diameter, a thickness or the like.

In the plasma processing apparatus 10, when the etching performed, plasma is generated in the processing chamber 1. At this time, due to an error in the state of the wafer W, a height of a plasma sheath may be changed and the etching characteristics may vary depending on wafers W. For example, in the plasma processing apparatus 10, the height of the plasma sheath above the wafer W is changed due to the error in the state of the wafer W. In the plasma processing apparatus 10, ions in the plasma are accelerated by a voltage applied to the plasma sheath and injected into the wafer W, thereby performing etching. Accordingly, in the plasma processing apparatus 10, when the height of the plasma sheath is changed, the etching characteristics are changed.

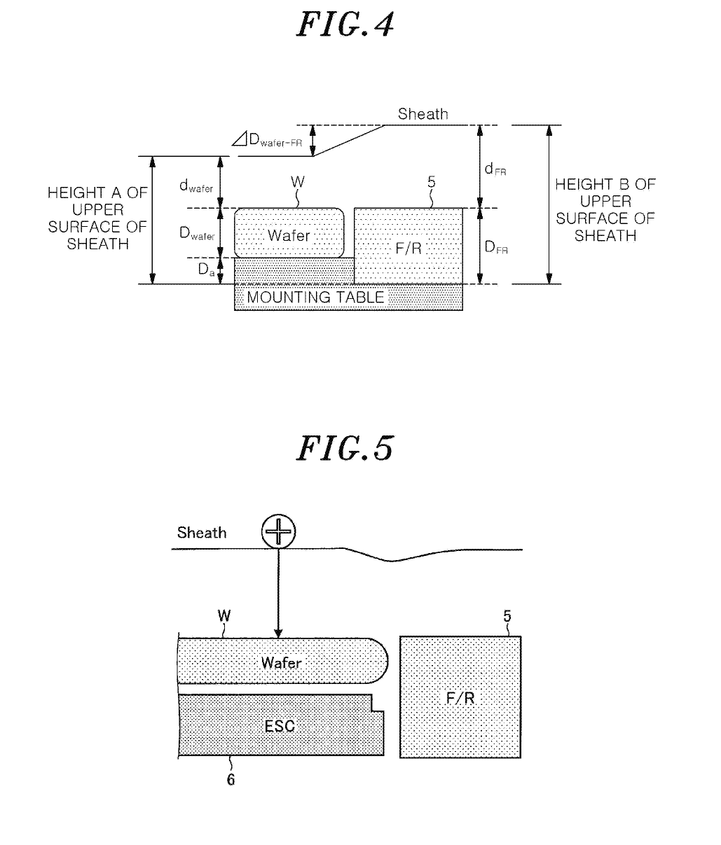

FIG. 4 schematically shows an example of the state of the plasma sheath. FIG. 4 shows the wafer W mounted on the mounting table and the focus ring 5. In FIG. 4, both of the first mounting table 2 and the second mounting table 7 are illustrated as the mounting table. D_{wafer} indicates a thickness of the wafer W. d_{wafer} indicates a height from the upper surface of the wafer W to the interface of the plasma sheath above the wafer W. A thickness Dₐ indicates a difference between the mounting surface of the mounting table on which the wafer W is mounted and the height of the mounting surface of the mounting table on which the focus ring 5 is mounted. For example, in the first embodiment, the thickness Dₐ indicates a difference in the height between the mounting surface 6d of the first mounting table 2 and the mounting surface 9d of the focus ring 5. The thickness Dₐ is determined as a fixed value depending on the configurations of the first mounting table 2 and the second mounting table 7. A thickness D_{FR} indicates a thickness of the focus ring 5. A thickness d_{FR} indicates a height from the upper surface of the focus ring 5 to the interface of the plasma sheath above the focus ring 5.

A difference Δ_{wafer-FR} between the interface of the plasma sheath above the wafer W and the interface of the plasma sheath above the focus ring 5 can be expressed by the following Eq. (1).

Δ_{wafer-FR}=(Dₐ+D_{wafer}+d_{wafer})−(D_{FR}+d_{FR}) Eq. (1)

For example, when the thickness D_{wafer} of the wafer W is changed due to an error, the difference Δ_{wafer-FR} is changed. Therefore, in the plasma processing apparatus 10, the etching characteristics change.

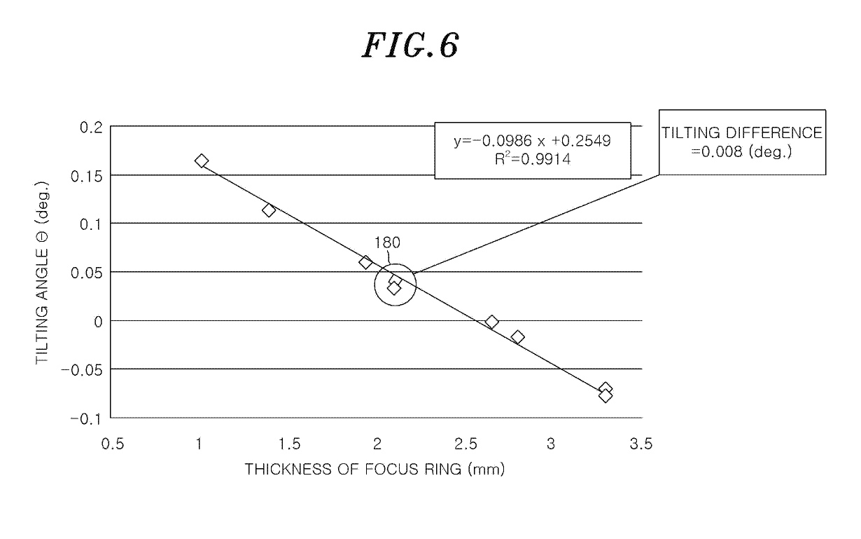

FIG. 5 schematically showing an ideal state of the plasma sheath. For example, as shown in FIG. 5, when the plasma sheath above the focus ring 5 is flush with the plasma sheath above the wafer W, positive charges of ions are vertically incident on the wafer W.

If there is an error in the state of the wafer W such as a diameter, a thickness, or the like, the height of the plasma sheath above the wafer W is changed and, thus, the incident angle of positive charges of ions with respect to the wafer W is changed. When the incident angle of the positive charges of ions is changed, the etching characteristics are changed. For example, shape abnormality such as tilting occurs in a hole being etched. The tilting is abnormality in which a hole is obliquely etched.

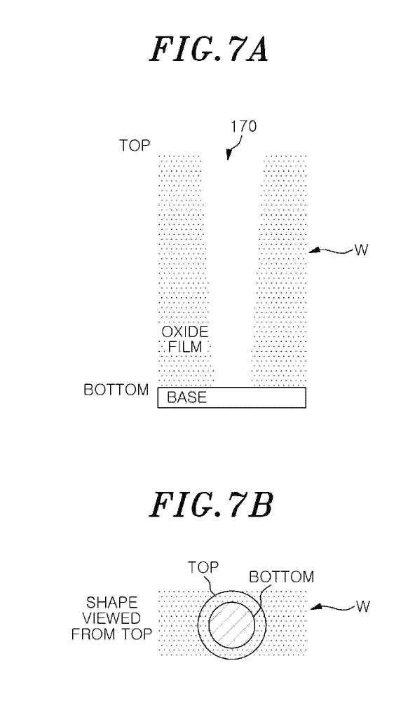

Therefore, even when the thickness of the focus ring 5 is constant, the etching characteristics may vary depending on wafers W. FIG. 6 shows an example of the relation between an angle θ of an etched hole and a thickness of the focus ring. In FIG. 6, the angle θ of the hole (tilting angle θ) was measured by etching holes while changing the thickness of the focus ring 5. For example, referring to FIG. 6, as indicated by a reference numeral 180, two tilting angles θ are plotted at the thickness of the focus ring 5 of 2.1 mm. The two tilting angles θ were measured by etching holes in two different wafers W. There is a difference of 0.008 (deg) between the two tilting angles θ indicated by the reference numeral 180.

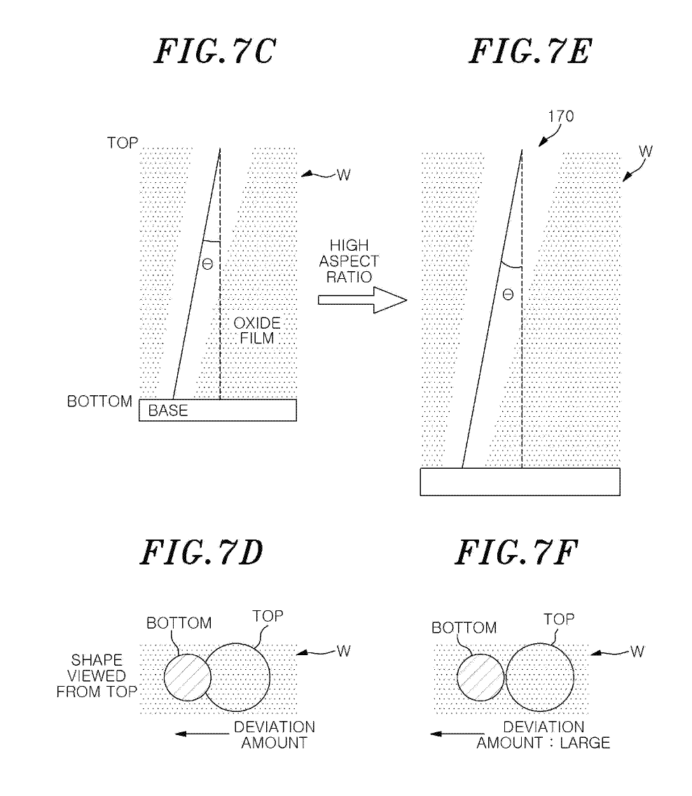

FIGS. 7A and 7B schematically show a state in which a hole is etched. FIG. 7A shows an ideal state in which a hole 170 is vertically etched in an oxide film of the wafer W. FIG. 7A shows a cross-sectional shape of the hole 170 etched in the oxide film. FIG. 7B shows a position (Top) of the hole 170 on the upper surface of the oxide film and a position (Bottom) on the bottom surface thereof in the case where the etched hole 170 is viewed from the top. When the hole 170 is etched in an ideal state, the position of the hole 170 on the upper surface is aligned with the position of the hole 170 on the bottom surface as can be seen from FIG. 7B.

FIGS. 7C to 7F schematically show a state in which a hole is etched. FIGS. 7C to 7F show a state in which the hole 170 is obliquely etched at an angle θ in the oxide film. FIG. 7C shows a cross-sectional shape of the hole 170 etched in the oxide film. FIG. 7D shows a position (Top) of the hole 170 on the upper surface of the oxide film and a position (Bottom) of the hole 170 on the bottom thereof in the case where the etched hole 170 is viewed from the top. When the hole 170 is etched obliquely, the position of the hole 170 on the upper surface is deviated from the position of the hole 170 on the bottom surface as can be seen from FIG. 7D.

Recently, in the plasma processing apparatus 10, the etching of a hole having a high aspect ratio is required. For example, in manufacturing a NAND flash memory having a three-dimensional structure, a bole to be etched has a high aspect ratio. However, when the aspect ratio of the hole to be etched is high, the positional deviation caused by the angle θ of the hole is increased.

FIGS. 7E and 7F show a state in which a hole having a high aspect ratio is obliquely etched at an angle θ in a thicker oxide film. FIG. 7E shows a cross-sectional shape of the hole 170 etched in the oxide film. FIG. 7F shows a position (Top) of the hole 170 on the upper surface of the oxide film and a position (Bottom) of the hole 170 on the bottom surface thereof in the case where the etched hole 170 is viewed from the top. When the aspect ratio of the hole is high, the deviation amount between the position of the hole 170 on the upper surface and the position of the hole 170 on the bottom surface is increased, as can be seen from FIG. 7F.

As described above, in the plasma processing apparatus 10, as the hole to be etched becomes deeper and the aspect ratio of the hole becomes higher, the changes in the etching characteristic due to the variation in the state of the wafer W become remarkable. Particularly, the peripheral portion of the wafer W is easily affected by the variation in the state of the wafer W.

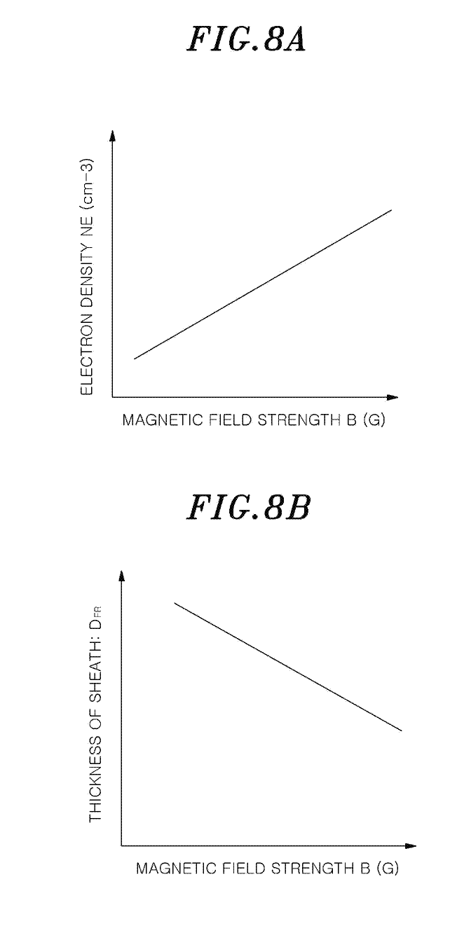

In the plasma processing apparatus 10, the plasma state is changed by magnetic forces from the electromagnets 60a to 60c. FIG. 8A is a graph showing an example of the relation between a magnetic field strength and an electron density of the plasma. As shown in FIG. 8A, the magnetic field strength of the magnetic force applied to the plasma is proportional to the electron density of the plasma.

The relation between the electron density of the plasma and the thickness of the plasma sheath is expressed by the following Eq. (2).

$$Sheath Thickness = \frac{\sqrt{2}}{3} ( \frac{{ɛ}_{0} {T}_{e}}{e \cdot {N}_{e}} ) {( \frac{2 {V}_{dc}}{{T}_{e}} )}^{3 / 4} \qquad ( 2 )$$

Here, Nₑ indicates the electron density of the plasma. Tₑ indicates the electron temperature (ev) of the plasma. V_{dc} indicates a potential difference between the wafer W and the plasma above the wafer W and between the focus ring 5 and the plasma above the focus ring 5.

As shown in Eq. (2), the thickness of the plasma sheath is in inverse proportion to the electron density Nₑ. Therefore, the magnetic field strength of the magnetic force applied to the plasma and the electron density of the plasma are in inverse proportion to each other. FIG. 8B is a graph showing an example of the relation between the magnetic field strength and the thickness of the plasma sheath. As shown in FIG. 8B, the thickness of the plasma sheath is in inverse proportion to the magnetic field strength of the magnetic force applied to the plasma.

Accordingly, in the plasma processing apparatus 10 according to the first embodiment, the magnetic field strength of the magnetic forces from the electromagnets 60a to 60c is controlled such that the variation in the etching characteristics of each wafer W is suppressed.

Referring back to FIG. 2, a correction value of the power supplied to the electromagnets 60a to 60c is stored, for each state of the wafer W, in the correction information 163b according to the first embodiment. For example, the amount of power supplied to the electromagnets 60a to 60c which ensures the magnetic field strength at which the difference Δ_{wafer-FR} between the height of the interface of the plasma sheath above the wafer W and the height of the interface of the plasma sheath above the focus ring 5 is within a predetermined range is experimentally measured for each thickness of the wafer W. For example, in the case of supplying AC power from the power supply to the electromagnets 60, any one of a voltage, a frequency, and a power level of the AC power is changed, and the changed one is measured as the amount of power. In the case of supplying DC power from the power supply to the electromagnets 60, either a voltage or a current of the DC power is changed, and the changed one is measured as the amount of power. The predetermined range is, e.g., a range of Δ_{wafer-FR} in which the angle θ (tilting angle θ) of the hole etched in the wafer W is within an allowable accuracy. The correction value of the power supplied to the electromagnets 60a to 60c at which the difference Δ_{wafer-FR} is within the predetermined range is stored, for each thickness of the wafer W, in the correction information 163b based on the measurement result. The correction value may be the amount of power at which the difference Δ_{wafer-FR} is within the predetermined range, or may be a difference between the measured amount of power and the standard amount of power supplied to the electromagnets 60a to 60c during the plasma processing. In the present embodiment, the correction value is the amount of power supplied to the electromagnets 60a to 60c.

In the plasma processing apparatus 10 according to the first embodiment, the height of the interface of the plasma sheath above the focus ring 5 is corrected by correcting the power supplied to the electromagnet 60c. The correction value of the power supplied to the electromagnet 60c is stored, for each state of the wafer W, in the correction information 163b. In the plasma processing apparatus 10, the height of the interface of the plasma sheath above the wafer W may be corrected by correcting the power supplied to the electromagnets 60a and 60b. In that case, the correction value of the power supplied to the electromagnets 60a and 60b is stored, for each state of the wafer W, in the correction information 163b. Further, in the plasma processing apparatus 10, the height of the interface of the plasma sheath above the focus ring 5 and the height of the interface of the plasma sheath above the wafer W may be corrected by correcting the power supplied to the electromagnets 60a to 60c, respectively. In that case, the correction value of the power supplied to the electromagnets 60a to 60c is stored, for each state of the wafer W, in the correction information 163b.

The acquisition unit 161a acquires the state information 163a of the wafer W as the plasma processing target. For example, the acquisition unit 161a acquires the state information 163a of the wafer W as the plasma processing target from the storage unit 163. The state information 163a includes data on the thickness of the wafer W. In the present embodiment, the state information 163a is previously stored in the storage unit 163. However, the state information 163a may be stored in another device. In that case, the acquisition unit 161a may acquire the state information 163a via a network.

The plasma control unit 161b controls the plasma processing such that the difference Δ_{wafer-FR} between the height of the interface of the plasma sheath above the wafer W and the height of the interface of the plasma sheath above the focus ring 5 is within the predetermined range.

The plasma control unit 161b controls the magnetic forces of the electromagnets 60a to 60c based on the state of the wafer W indicated by the state information 163a acquired by the acquisition unit 161a such that the difference Δ_{wafer-FR} between the height of the interface of the plasma sheath above the wafer W and the height of the interface of the plasma sheath above the focus ring 5 is within the predetermined range. For example, the plasma control unit 161b obtains the thickness of the wafer W as the processing target mounted on the first mounting table 2 from the state information 163a acquired by the acquisition unit 161a. The plasma control unit 161b reads out the correction value of the power supplied to the electromagnets 60a to 60c which correspond to the thickness of the wafer W as the processing target from the correction information 163b. Further, the plasma control unit 161b controls the power supply connected to the electromagnets 60a to 60c to supply the corrected power to the electromagnets 60a to 60c during the plasma processing. In the present embodiment, the plasma control unit 161b controls the power supply connected to the electromagnet 60c to supply the corrected power to the electromagnet 60c.

Accordingly, in the plasma processing apparatus 10, the difference Δ_{wafer-FR} between the height of the interface between the plasma sheath above the wafer W and the height of the interface of the plasma sheath above the focus ring 5 is within the predetermined range, and the variation in etching characteristics of each wafer W can be suppressed.

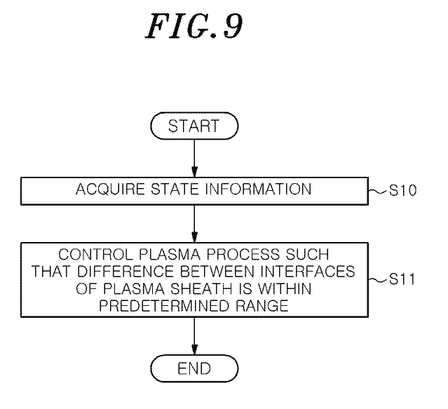

Next, a plasma control process using the plasma processing apparatus 10 according to the first embodiment will be described. FIG. 9 is a flowchart showing an example of the sequence of the plasma control process. This plasma control process is performed at predetermined timing, e.g., when the wafer W is mounted on the first mounting table 2 and a temperature in the processing chamber 1 is stabilized to a level at which the plasma processing is performed. Alternatively, the plasma control process may be performed when the wafer W is mounted on the first mounting table 2.

As shown in FIG. 9, the acquisition unit 161a acquires the state information 163a of the wafer W as the plasma processing target (step S10).

The plasma control unit 161b controls the plasma processing based on the state of the wafer W indicated by the acquired state information 163a such that the difference between the height of the interface of the plasma sheath above the wafer W and the height of the interface of the plasma sheath above the focus ring 5 is within the predetermined range (step S11). For example, the plasma control unit 161b controls the magnetic forces of the electromagnets 60a to 60c based on the state of the wafer W such that the difference Δ_{wafer-FR} between the height of the interface of the plasma sheath above the wafer W and the height of the interface of the plasma sheath above the focus ring 5 is within the predetermined range, and the process is terminated.

As described above, the plasma processing apparatus 10 according to the first embodiment includes the first mounting table 2, the focus ring 5, the acquisition unit 161a, and the plasma control unit 161b. The first mounting table 2 mounts thereon the wafer W as the plasma processing target. The focus ring 5 is placed to surround the wafer W. The acquisition unit 161a acquires the state information 163a indicating a measured state of the wafer W. The plasma control unit 161b controls the plasma processing based on the state of the wafer W indicated by the acquired state information 163a, such that the difference between the height of the interface of the plasma sheath above the wafer W and the height of the interface of the plasma sheath above the focus ring 5 is within the predetermined range. Accordingly, the plasma processing apparatus 10 can suppress the variation in the etching characteristics of each wafer W. Particularly, the plasma processing apparatus 10 can suppress the variation in the etching characteristics of each wafer W at the peripheral portion of the wafer W which is easily affected by the variation in the state of the wafer W. Further, the plasma processing apparatus 10 can perform etching while suppressing the deviation amount between the position of the hole on the upper surface and the position of the hole on the bottom surface in each wafer W even in the case of etching a hole having a high aspect ratio.

The plasma processing apparatus 10 according to the first embodiment further includes one or more electromagnets 60 arranged in parallel with at least one of the wafer W and the focus ring 5. The plasma control unit 161b controls the magnetic forces of the electromagnets 60 based on the state of the wafer W such that the difference between the height of the interface of the plasma sheath above the wafer W and the height of the interface of the plasma sheath above the focus ring 5 is within the predetermined range by controlling the power supplied to the electromagnets 60. Accordingly, the plasma processing apparatus 10 can suppress the variation in the etching characteristics of each wafer W.

### Second Embodiment

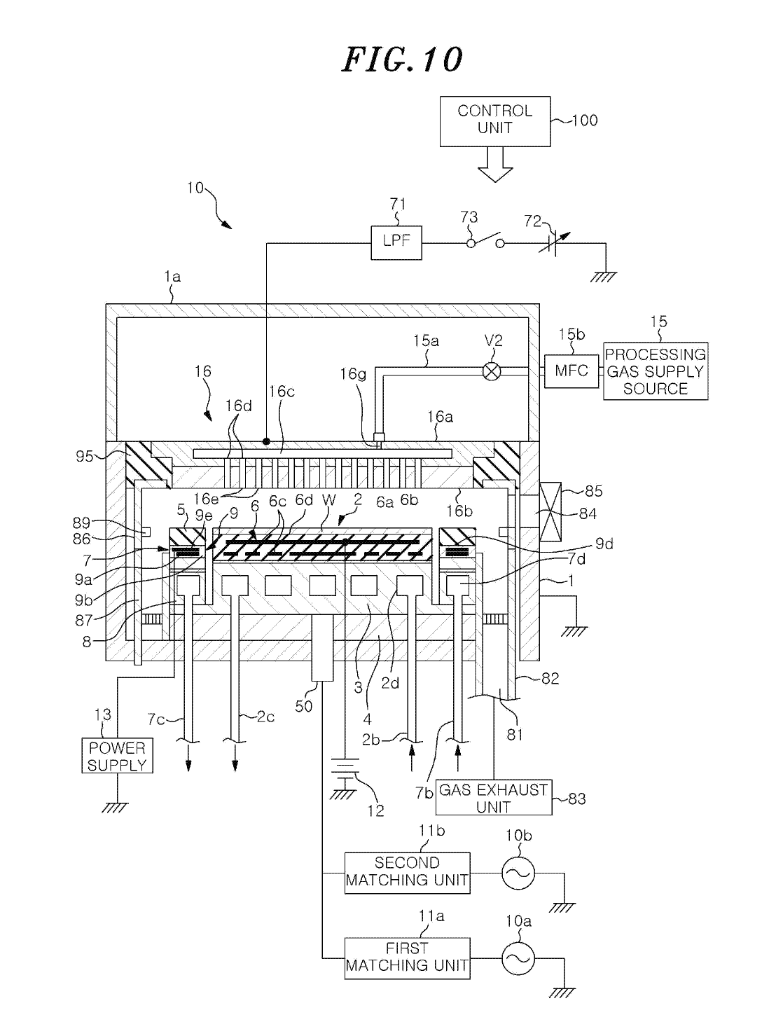

Next, a second embodiment will be described. FIG. 10 is a schematic cross-sectional view showing an example of a schematic configuration of a plasma processing apparatus according to the second embodiment. Since the configuration of the plasma processing apparatus 10 according to the second embodiment is the same as that of the plasma processing apparatus 10 according to the first embodiment, like reference numerals will be given to like parts and differences will be mainly described.

In a second mounting table 7 according to the second embodiment, an electrode is provided on the mounting surface 9d on which the focus ring 5 is mounted. In the second mounting table 7 according to the second embodiment, an electrode 9e is provided in the focus ring heater unit 9 along the circumferential direction. The electrode 9e is electrically connected to a power supply 13 via a wiring. The power supply 13 according to the second embodiment is a DC power supply for applying a DC voltage to the electrode 9e.

The plasma state is changed due to changes in the electrical characteristics of the ambient environment. For example, the plasma state above the focus ring 5 is changed depending on the magnitude of the DC voltage applied to the electrode 9e, and the thickness of the plasma sheath is changed.

Therefore, in the plasma processing apparatus 10 according to the second embodiment, the DC voltage to be applied to the electrode 9e is controlled to suppress the variation in the etching characteristics of each wafer W.

A correction value of the DC voltage applied to the electrode 9e is stored, for each state of the wafer W, in the correction information 163b according to the second embodiment. For example, the DC voltage applied to the electrode 9e at which the difference Δ_{wafer-FR} between the height of the interface of the plasma sheath above the wafer W and the height of the interface of the plasma sheath above the focus ring 5 is within the predetermined range is experimentally measured for each thickness of the wafer W. The correction value of the DC voltage applied to the electrode 9e at which the difference Δ_{wafer-FR} is within the predetermined range is stored, for each thickness of the wafer W, in the correction information 163b based on the measurement result. The correction value may be the DC voltage at which the difference Δ_{wafer-FR} is within the predetermined range, or may be a difference between the measured DC voltage and the standard DC voltage applied to the electrode 9e during the plasma processing. In the present embodiment, the correction value is the DC voltage applied to the electrode 9e.

The plasma control unit 161b controls the DC voltage applied to the electrode 9e based on the state of the wafer W indicated by the state information 163a acquired by the acquisition unit 161a such that the difference Δ_{wafer-FR} between the height of the interface of the plasma sheath above the wafer W and the height of the interface of the plasma sheath above the focus ring 5 is within the predetermined range. For example, the plasma control unit 161b obtains a thickness of the wafer W as the target object mounted on the first mounting table 2 from the state information 163a acquired by the acquisition unit 161a. The plasma control unit 161b reads out the correction value of the DC voltage applied to the electrode 9e which corresponds to the thickness of the wafer W as the target object from the correction information 163b. Then, the plasma control unit 161b controls the power supply 13 to supply the corrected DC voltage to the electrode 9e during the plasma processing.

Accordingly, in the plasma processing apparatus 10, the difference Δ_{wafer-FR} between the height of the interface of the plasma sheath above the wafer W and the height of the interface of the plasma sheath above the focus ring 5 is within the predetermined range, and the variation in the etching characteristics of each wafer W can be suppressed.

As described above, the plasma processing apparatus 10 according to the second embodiment further includes the electrode 9e provided on the mounting surface 9d on which the focus ring 5 is mounted and to which the DC voltage is applied. The plasma control unit 161b controls the DC voltage applied to the electrode 9e based on the state of the wafer W such that the difference between the height of the interface of the plasma sheath above the wafer W and the height of the interface of the plasma sheath above the focus ring 5 is within the predetermined range. Accordingly, the plasma processing apparatus 10 can suppress the variation in the etching characteristics of each wafer W.

### Third Embodiment

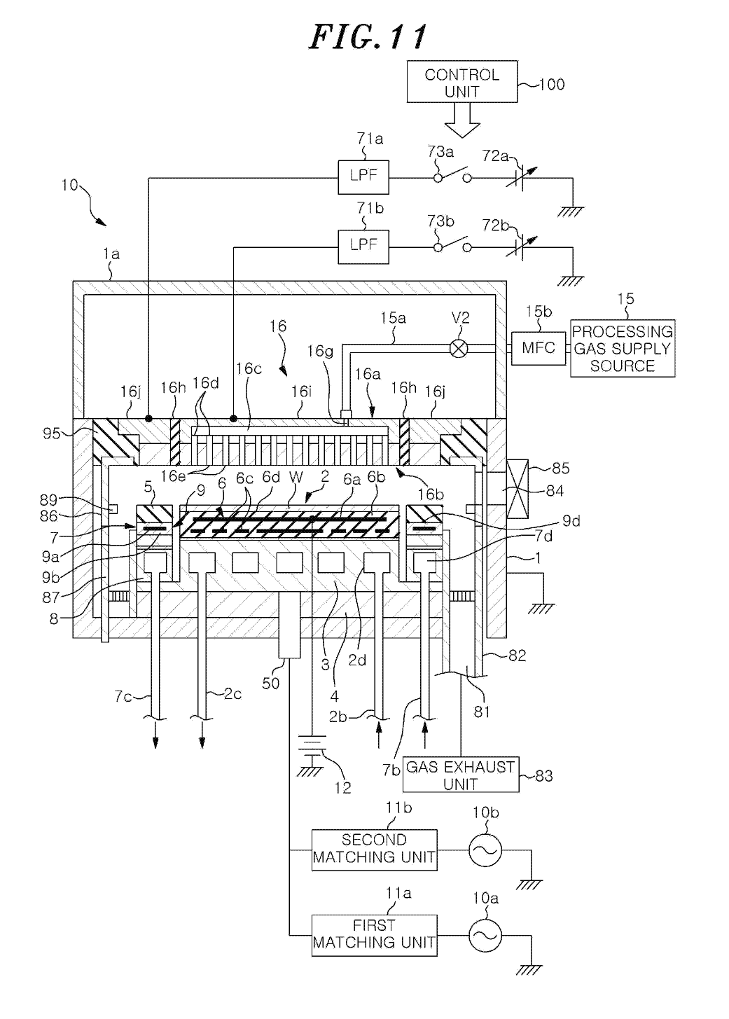

Next, a third embodiment will be described. FIG. 11 is a schematic cross-sectional view showing an example of a schematic configuration of a plasma processing apparatus according to a third embodiment. Since the configuration of the plasma processing apparatus 10 according to the third embodiment is partially similar to that of the plasma processing apparatus 10 according to the first embodiment, like reference numerals will be given to like parts, and differences will be mainly described.

A main body 16a and a ceiling plate 16b of the shower head 16 according to the third embodiment are divided into a plurality of parts by an insulating member. For example, the main body 16a and the ceiling plate 16b are divided into a central part 16i and a peripheral part 16j by an annular insulating member 16h. The central part 16i has a disc shape and is disposed above the central portion of the first mounting table 2. The peripheral part 16j has an annular shape and is disposed above the peripheral portion of the first mounting table 2 to surround the central part 16i.

In the shower head 16 according to the third embodiment, a DC current can be individually applied to each divided part, and each divided part serves as an upper electrode. For example, a variable DC power supply 72a is electrically connected to the peripheral part 16j via a low pass filter (LPF) 71a and an on/off switch 73a. A variable DC power supply 72b is electrically connected to the central part 16i via an LPF 71b and an on/off switch 73b. The power applied to the central part 16i and the peripheral part 16j by the variable DC power supplies 72a and 72b can be controlled by the control unit 100. The central part 16i and the peripheral part 16j serve as electrodes.

The plasma state is changed due to the changes in the electrical characteristics of the ambient environment. For example, in the plasma processing apparatus 10, the plasma state is changed depending on voltages applied to the central part 16i and the peripheral part 16j.

Therefore, in the plasma processing apparatus 10 according to the third embodiment, the voltages applied to the central part 16i and the peripheral part 16j is controlled such that the variation in the etching characteristics of each wafer W is suppressed.

Correction values of the DC voltages applied to the central part 16i and the peripheral part 16j are stored, for each state of the wafer W, in the correction information 163b according to the third embodiment. For example, the DC voltages applied to the central part 16i and the peripheral part 16j at which the difference Δ_{wafer-FR} between the height of the interface of the plasma sheath above the wafer W and the height of the interface of the plasma sheath above the focus ring 5 is within the predetermined range are experimentally measured for each thickness of the wafer W. The correction values of the DC voltages applied to the central part 16i and the peripheral part 16j at which the difference Δ_{wafer-FR} is within the predetermined range are stored, for each thickness of the wafer W, in the correction information 163b based on the measurement result. The correction values may be the DC voltages applied to the central part 16i and the peripheral part 16j, or may be a difference between the measured DC voltages and the standard DC voltages applied to the central part 16i and the peripheral part 16j during the plasma processing. In the present embodiment, the correction values are the DC voltages applied to the central part 16i and the peripheral part 16j.

In the plasma processing apparatus 10 according to the third embodiment, the height of the interface of the plasma sheath above the focus ring 5 is corrected by correcting the DC voltage applied to the peripheral part 16j. The correction value of the DC voltage applied to the peripheral part 16j is stored, for each state of the wafer W, in the correction information 163b. Further, in the plasma processing apparatus 10, the shower head 16 is further divided into a plurality of annular parts such that the height of the interface of the plasma sheath above the wafer W can be corrected by correcting DC voltages applied to the respective annular parts of the shower head 16. In that case, the correction values of the DC voltages applied to the respective annular parts of the shower head 16 are stored, for each state of the wafer W, in the correction information 163b. Moreover, in the plasma processing apparatus 10, the height of the interface of the plasma sheath above the focus ring 5 and the height of the interface of the plasma sheath above the wafer W can be corrected by correcting the DC voltages applied to the respective annular parts of the shower head 16. In that case, the correction values of the DC voltages applied to the respective annular parts of the shower head 16 are stored, for each state of the wafer W, in the correction information 163b.

The plasma control unit 161b controls the DC voltage applied to the peripheral part 16j based on the state of the wafer W indicated by the state information 163a acquired by the acquisition unit 161a such that the difference Δ_{wafer-FR} between the height of the interface of the plasma sheath above the wafer W and the height of the interface of the plasma sheath above the focus ring 5 is within the predetermined range. For example, the plasma control unit 161b obtains the thickness of the wafer W as the processing target mounted on the first mounting table 2 from the state information 163a acquired by the acquisition unit 161a. The plasma control unit 161b reads out the correction value of the DC voltage applied to the peripheral part 16j which corresponds to the thickness of the wafer W as the processing target from the correction information 163b. Then, the plasma control unit 161b controls the variable DC power supply 72a to supply the corrected DC voltage to the peripheral part 16j during the plasma processing.

Accordingly, in the plasma processing apparatus 10, the difference Δ_{wafer-FR} between the height of the interface between the plasma sheath above the wafer W and the height of the interface of the plasma sheath above the focus ring 5 is within the predetermined range, and the variation in the etching characteristics of each wafer W can be suppressed.

As described above, the shower head 16 according to the third embodiment, which injects the processing gas, includes the central part 16i and the peripheral part 16j disposed to face the wafer W and the focus ring 5 in parallel with at least one of the wafer W and the focus ring 5 and serving as electrodes. The plasma control unit 161b controls the power supplied to the central part 16i and the peripheral part 16j based on the state of the wafer W such that the difference between the height of the interface of the plasma sheath above the wafer W and the height of the interface of the plasma sheath above the focus ring 5 is within the predetermined range. Accordingly, the plasma processing apparatus 10 can suppress the variation in the etching characteristics of each wafer W.

### Fourth Embodiment

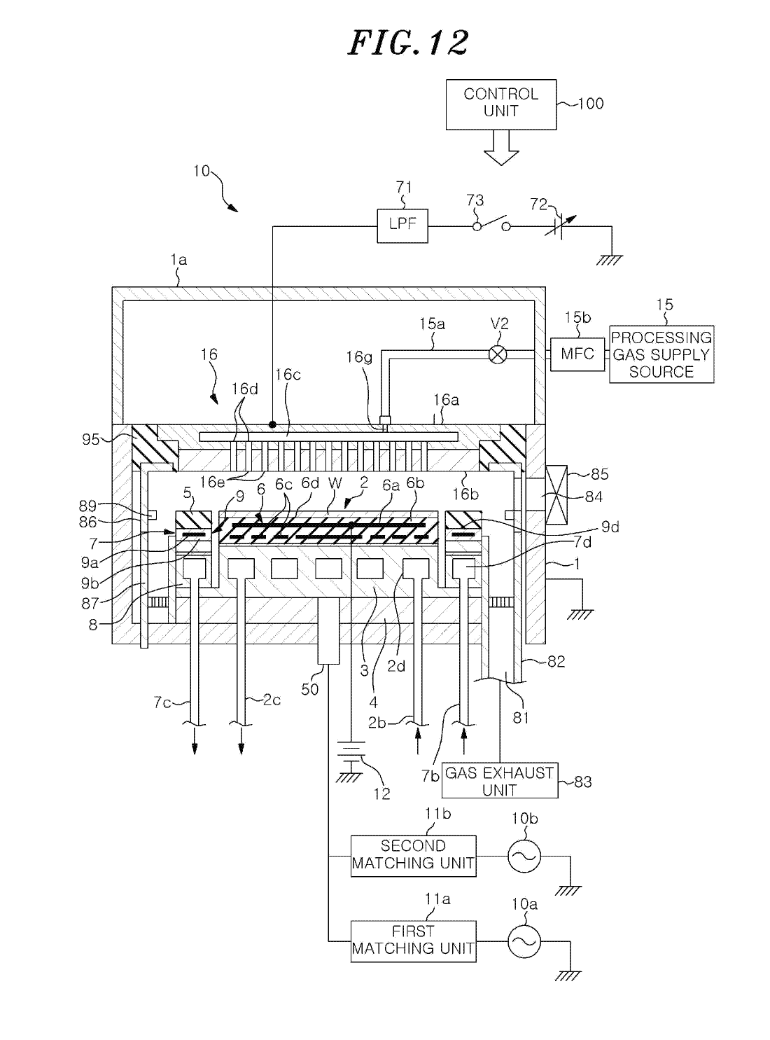

Next, a fourth embodiment will be described. FIG. 12 is a schematic cross-sectional view showing an example of a schematic configuration of a plasma processing apparatus according to the fourth embodiment. Since the configuration of the plasma processing apparatus 10 according to the fourth embodiment is partially similar to that of the plasma processing apparatus 10 according to the first embodiment, like reference numerals will be given to like parts, and differences will be mainly described. In the plasma processing apparatus 10 according to the fourth embodiment, the electromagnets 60 are not provided on the upper surface of the shower head 16, and the second mounting table 7 can be vertically moved.

<Configurations of the First Mounting Table and the Second Mounting Table>

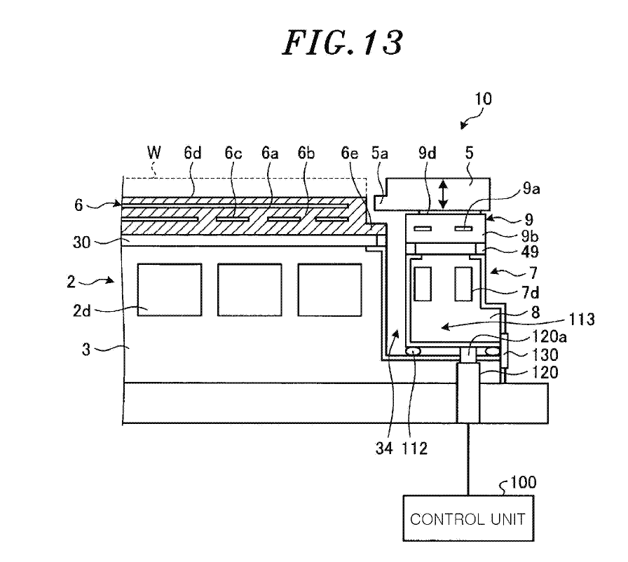

Next, the configurations of main parts of the first mounting table 2 and the second mounting table 7 according to the fourth embodiment will be described with reference to FIG. 13. FIG. 13 is a schematic cross-sectional view of the main configuration of the first mounting table and the second mounting table according to the fourth embodiment.

The first mounting table 2 includes a base 3 and an electrostatic chuck 6. The electrostatic chuck 6 is adhered to the base 3 via an insulating layer 30. The electrostatic chuck 6 is formed in a disc shape and provided coaxially with respect to the base 3. In the electrostatic chuck 6, an electrode 6a is provided in the insulator 6b. The upper surface of the electrostatic chuck 6 serves as a mounting surface 6d on which the wafer W is mounted. A flange portion 6e projecting outwardly in a radial direction of the electrostatic chuck 6 is formed at a lower end of the electrostatic chuck 6. In other words, the electrostatic chuck 6 has different outer diameters depending on positions of the side surface thereof.

In the electrostatic chuck 6, a heater 6c is provided in the insulator 6b. A coolant path 2d is formed in the base 3. The coolant path 2d and the heater 6c function as a temperature control mechanism for controlling a temperature of the wafer W. The heater 6c may not be provided in the insulator 6b. For example, the heater 6c may be adhered to the lower surface of the electrostatic chuck 6 or may be interposed between the mounting surface 6d and the coolant path 2d. Further, a single heater 6c may be provided for the entire mounting surface 6d or may be provided for each of a plurality of divided regions of the mounting surface 6d. In other words, a plurality of heaters 6c may be provided for the respective divided regions of the mounting surface 6d. For example, the heater 6c may extend in an annular shape about the center of the first mounting table 2 in each of a plurality of regions obtained by concentrically dividing the mounting surface 6d of the first mounting table 2. Alternatively, heater may include heater for heating a central region and a heater extending in an annular shape to surround the outside of the central region. The heater 6c may be provided in each of a plurality of regions obtained by radially dividing the region extending in an annular shape about the center of the mounting surface 6d.

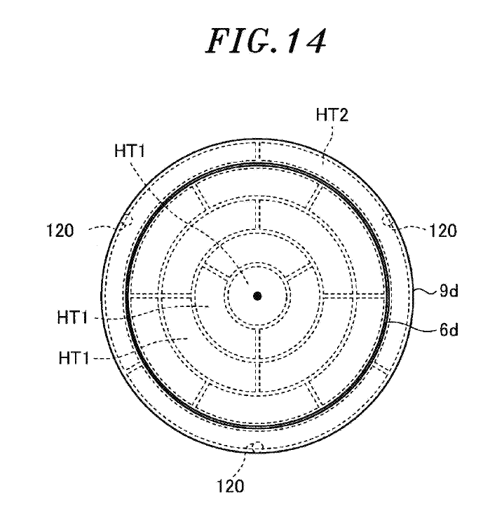

FIG. 14 is a top view of the first mounting table and the second mounting table according to the fourth embodiment which is viewed from the top. Referring to FIG. 14, the mounting surface 6d of the first mounting table 2 has a disc shape. The mounting surface 6d is divided into a plurality of regions HT1 based on the distance and direction from the center. The heater 6c is provided in each of the regions HT1. Accordingly, the plasma processing apparatus 10 can control a temperature of the wafer W in each of the regions HT1.

Referring back to FIG. 13, the second mounting table 7 includes the base 8 and the focus ring heater unit 9. The base 8 is supported by the base 3. In the focus ring heater unit 9, the heater 9a is provided in the insulator 9b. The coolant path 7d is formed in the base 8. The coolant path 7d and the heater 9a function as a temperature control mechanism for controlling a temperature of the focus ring 5. The focus ring heater unit 9 is adhered to the base 8 through an insulating layer 49. An upper surface of the focus ring heater unit 9 serves as the mounting surface 9d on which the focus ring 5 is mounted. A sheet member having high thermal conductivity or the like may be provided on the upper surface of the focus ring heater unit 9.

The focus ring 5 that is an annular member is coaxially arranged with the second mounting table 7. A protruding portion 5a protrudes in a radial direction from an inner side surface of the focus ring 5. In other words, the focus ring 5 has different inner diameters depending on positions of the inner side surface thereof. For example, an inner diameter of a portion of the focus ring 5 where the protruding portion. 5a is not formed is greater than an outer diameter of the wafer W and an outer diameter of the flange portion 6e of the electrostatic chuck 6. On the other hand, an inner diameter of a portion of the focus ring 5 where the protruding portion 5a is formed is smaller than the outer diameter of the flange portion 6e of the electrostatic chuck 6 and greater than an outer diameter of a portion of the electrostatic chuck. 6 where the flange portion 6e is not formed.

The focus ring 5 is disposed on the second mounting table 7 in a state where the protruding portion 5a is separated from an upper surface of the flange portion 6e of the electrostatic chuck 6 and also separated from a side surface of the electrostatic chuck 6. In other words, a gap is formed between a lower surface of the protruding portion 5a of the focus ring 5 and the upper surface of the flange portion 6e of the electrostatic chuck 6. In addition, a gap is formed between a side surface of the protruding portion 5a of the focus ring 5 and a side surface of the electrostatic chuck. 6 where the flange portion 6e is not formed. The protruding portion 5a of the focus ring 5 is located above a gap 34 between the base 3 of the first mounting table 2 and the base 8 of the second mounting table 7. In other words, when viewed from a direction perpendicular to the mounting surface 6d, the protruding portion 5a overlaps with the gap 34 and covers the gap 34. Accordingly, it is possible to suppress inflow of the plasma into the gap 34.

The heater 9a has an annular shape coaxial with the base 8. A single heater ha may be provided for the entire mounting surface 9d or may be provided for each of a plurality of divided regions of the mounting surface 9d. In other words, a plurality of heaters ha may be provided for the respective divided regions of the mounting surface 9d. For example, the heater 9a may be provided in each of a plurality of regions obtained by circumferentially dividing the mounting surface 9d of the second mounting table 7. For example, in FIG. 14, the mounting surface 9d of the second mounting table 7 is provided around the mounting surface 6d of the first mounting table 2. The mounting surface 9d is circumferentially divided into a plurality of regions HT2, and the heater ha is provided in each of the regions HT2. Accordingly, the plasma processing apparatus 10 can control a temperature of the focus ring 5 in each of the regions HT2.

Referring back to FIG. 13, an elevation mechanism 120 for vertically moving the second mounting table 7 is provided at the first mounting table 2. For example, the elevation mechanism. 120 is provided at the first mounting table 2 to be positioned below the second mounting table 7. The elevation mechanism 120 has therein an actuator and vertically moves the second mounting table 7 by extending/contracting a rod 120a by using driving force of the actuator. The elevation mechanism 120 may obtain driving force for extending/contracting the rod. 120a by converting the driving force of the motor by a gear or the dike or may obtain driving force for extending/contracting the rod 120a by a hydraulic pressure or the like. An O-ring 112 for shielding vacuum is provided between the first mounting table 2 and the second mounting table 7.

The second mounting table 7 is configured not to be affected even when it is moved up. For example, the coolant path 7d is configured as a flexible line or a mechanism that can supply a coolant even when the second mounting table 7 is vertically moved. The wiring for supplying power to the heater 9a is configured as a flexible wiring or a mechanism that is electrically connected even when the second mounting table 7 is vertically moved.

In addition, the first mounting table 2 is provided with a conducting part 130 electrically connected to the second mounting table 7. The conducting part 130 is configured to electrically connect the first mounting table and the second mounting table 7 even when the second mounting table 7 is vertically moved by the elevation mechanism 120. For example, the conducting part 130 is configured as a flexible wiring or a mechanism that is electrically connected by contact between a conductor and the base 8 even when the second mounting table 7 is vertically moved. The conducting part 130 is provided so that the second mounting table 7 and the first mounting table 2 have equal electrical characteristics. For example, a plurality of conducting parts 130 is provided on circumferential surface of the first mounting table 2. The RF power supplied to the first mounting table 2 is also supplied to the second mounting table 7 through the conducting part 130. Alternatively, the conducting part 130 may be provided between the upper surface of the first mounting table 2 and the lower surface of the second mounting table 7.

The elevation mechanism 120 is arranged at a plurality of positions in the circumferential direction of the focus ring 5. In the plasma processing apparatus 10 of the present embodiment, three elevation mechanisms 120 are provided. For example, the elevation mechanisms 120 are arranged at the second mounting table 7 at a regular interval in a circumferential direction of the second mounting table 1. FIG. 14 shows arrangement positions of the elevation mechanisms 120. The elevation mechanisms 120 are disposed at the second mounting table 7 at an interval of 120° in the circumferential direction of the second mounting table 7. Four or more elevation mechanisms 120 may be provided at the second mounting table 7.

The plasma state is changed due to changes in the electrical characteristics of the ambient environment. For example, in the plasma processing apparatus 10, the plasma state is changed depending on a distance from the focus ring 5.

Therefore, in the plasma processing apparatus 10 according to the fourth embodiment, the vertical movement of the focus ring 5 is controlled to suppress the variation in the etching characteristics of each wafer W.

A correction value for vertically moving the focus ring 5 is stored, for each state of the wafer W, in the correction information 163b according to the fourth embodiment. For example, the height of the focus ring 5 at which the difference Δ_{wafer-FR} between the height of the interface of the plasma sheath above the wafer W and the height of the interface of the plasma sheath above the focus ring 5 is within the predetermined range is experimentally measured for each thickness of the wafer W. The correction value of the height of the focus ring 5 at which the difference Δ_{wafer-FR} is within the predetermined range is stored, for each thickness of the wafer W, in the correction information 163b based on the measurement result. The correction value may be the height of the focus ring 5 at which the difference Δ_{wafer-FR} is within the predetermined range, or may be a difference between the measured height of the focus ring 5 and the standard height of the focus ring 5 during the plasma processing. In the present embodiment, the correction value is the height of the focus ring 5.

The plasma control unit 161b controls the elevation mechanisms 120 based on the state of the wafer W indicated by the state information 163a acquired by the acquisition unit 161a such that the difference Δ_{wafer-FR} between the height of the interface of the plasma sheath above the wafer W and the height of the interface of the plasma sheath above the focus ring 5 is within the predetermined range. For example, the plasma control unit 161b obtains the thickness of the wafer W as the processing target mounted on the first mounting table 2 from the state information 163a acquired by the acquisition unit 161a. The plasma control unit 161b reads out the correction value of the height of the focus ring 5 which corresponds to the thickness of the wafer W as the processing target from the correction information 163b. Then, the plasma control unit 161b controls the elevation mechanisms 120 to vertically move the focus ring 5 to the corrected height during the plasma processing.

Accordingly, in the plasma processing apparatus 10, the difference Δ_{wafer-FR} between the height of the interface between the plasma sheath above the wafer W and the height of the interface of the plasma sheath above the focus ring 5 is within the predetermined range, and the variation in the etching characteristics of each wafer W can be suppressed.

As described above, the plasma processing apparatus 10 according to the fourth embodiment includes the elevation mechanisms 120 for vertically moving the focus ring 5. The plasma control unit 161b controls the elevation mechanisms 120 based on the state of the wafer W such that the difference between the height of the interface of the plasma sheath above the wafer W and the height of the interface of the plasma sheath above the focus ring 5 is within the predetermined range. Accordingly, the plasma processing apparatus 10 can suppress the variation in the etching characteristics of each wafer W.

### Fifth Embodiment

Next, a fifth embodiment will be described. Since the plasma processing apparatus 10 according to the fifth embodiment has the same configuration as the plasma processing apparatus 10 according to the fourth embodiment, the redundant description thereof will be omitted. The plasma processing apparatus 10 according to the fifth embodiment can further measure the thickness of the wafer W.

<Configuration of the First Mounting Table and the Second Mounting Table>

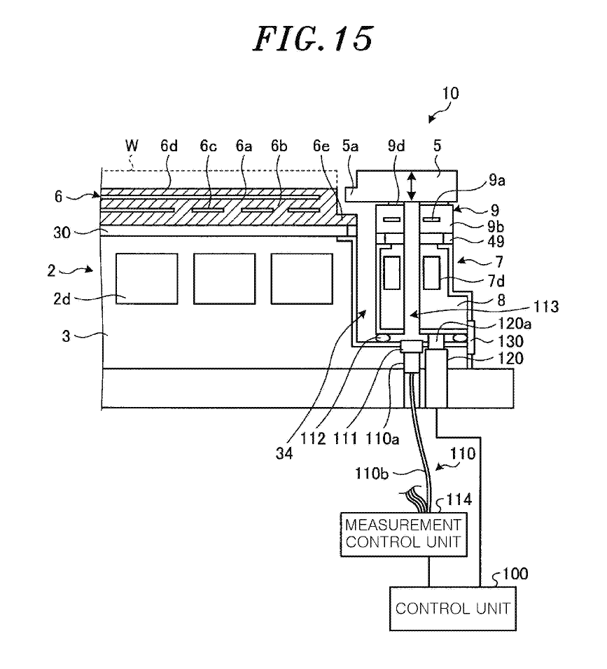

FIG. 15 is a schematic cross-sectional view showing configurations of main parts of the first mounting table and the second mounting table according to the fifth embodiment. The configurations of the first mounting table 2 and the second mounting table 7 according to the fifth embodiment are partially similar to those of the first mounting table 2 and the second mounting table 7 shown in FIG. 13. Therefore, like reference numerals will be given to like parts, and differences will be mainly described.

A measuring unit 110 for measuring a height of the upper surface of the focus ring 5 is provided at the second mounting table 7. In the present embodiment, the measuring unit 110 constitutes an optical interferometer for measuring a distance by using interference of laser light. The measuring unit 110 includes a light emitting part 110a and an optical fiber 110b. The light emitting part 110a is provided at the first mounting table 2 to be positioned below the second mounting table 7. A quartz window for shielding vacuum is provided at upper portion of the light emitting part 110a. A hole 113 penetrating through the second mounting table 7 from the lower surface thereof to the upper surface thereof is formed at position corresponding to the position where the measuring unit 110 is provided. A member that transmits laser light may be provided in the hole 113.

The light emitting part 110a is connected to a measurement control unit 114 through the optical fiber 110b. The measurement control unit 114 has therein a light source for generating laser light for measurement. The laser light generated in the measurement control unit 114 is emitted from the light emitting part 110a through the optical fiber 110b. The laser light emitted from the light emitting part 110a is partially reflected by the quartz window 111 or the focus ring 5. The reflected laser light is incident on the light emitting part 110a.

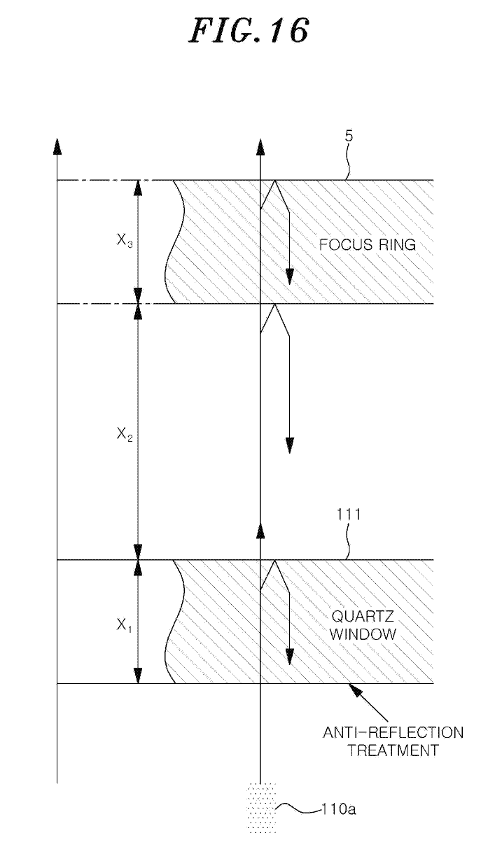

FIG. 16 shows a reflection system of laser light surface of the quartz window 111 which faces the light emitting part 110a is subjected to anti-reflection treatment and, thus, the reflection of the laser light on that surface is reduced. As shown in FIG. 16, a part of the laser light emitted from the light emitting part 110a is mainly reflected on the upper surface of the quartz window 111, the lower surface of the focus ring 5, and the upper surface of the focus ring 5, and is incident on the light emitting part. 110a.

The light incident on the light emitting part 110a is guided to the measurement control unit 114 through the optical fiber 110b. The measurement control unit 114 has therein a spectrometer or the like and measures a distance based on the interference state of the reflected laser light. For example, the measurement control unit 114 detects an intensity of light for each mutual distance between reflective surfaces based on the interference state of the incident laser light.

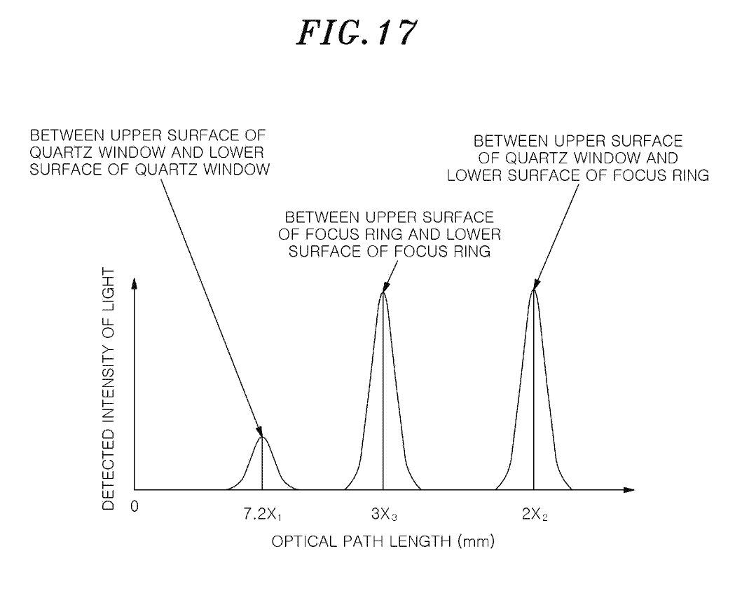

FIG. 17 shows an example of distribution of detected intensities of tight. The measurement control unit 114 detects the intensity of the fight while setting a mutual distance between the reflective surfaces as an optical path length. The horizontal axis in the graph of FIG. 17 represents the mutual distance set as the optical path length. “0” on the horizontal axis represents the origin of all mutual distances. The vertical axis in the graph of FIG. 17 represents the detected intensity of the light. The optical interferometer measures the mutual distance from the interference state of the reflected light. In the reflection, the light reciprocates the optical path of the mutual distance. Therefore, the optical path length is measured by “mutual distance×2×refractive index”. For example, when a thickness of the quartz window 111 is X₁ and the refractive index of quartz is 3.6, the optical path length to the upper surface of the quartz window 111 from the lower surface of the quartz window 111 is calculated as X₁×2×3.6=7.2X₁. In the example shown in FIG. 17, the intensity of the light reflected on the upper surface of the quartz window 111 has a peak at an optical path length of 7.2X₁. When a thickness of the hole 113 is X₂ and the refractive index inside the hole 113 where air exists is 1.0, the optical path length to the lower surface of the focus ring 5 from the upper surface of the quartz window 111 is calculated as X₂×2×1.0=2X₂. In the example shown in FIG. 17, the intensity of the light reflected on the lower face of the focus ring 5 has a peak at an optical path length of 2X₂. When a thickness of the focus ring 5 made of silicon is X₃ and the refractive index of the focus ring 5 is 1.5, the optical path length to the upper surface of the focus ring 5 from the lower surface of the focus ring 5 is calculated as X₃×2×1.5=3X₃. In the example shown in FIG. 17, the intensity of the light reflected on the upper surface of the focus ring 5 has a peak at an optical path length of 3X₃.

The thickness and the material of a new focus ring 5 are known. The thickness and the refractive index of the material of the new focus ring 5 are registered in the measurement control unit 114. The measurement control unit 114 calculates an optical path length corresponding to the thickness and the refractive index of the material of the new focus ring 5 and measures the thickness of the focus ring 5 from a peak position of the light having the peak intensity near the calculated optical path length. For example, the measurement control unit 114 measures the thickness of the focus ring 5 from the peak position of the light having the peak intensity near the optical path length of 3X₃. The measurement control unit. 114 adds all mutual distances between reflective surfaces to the upper surface of the focus ring 5 and measures the height of the upper surface of the focus ring 5. The measurement control unit 114 outputs the measurement result to the control unit 100. Further, the measurement control unit 114 may output the thickness of the focus ring 5 as the measurement result to the control unit 100. The thickness of the focus ring 5 may be measured by the control unit 100. For example, the measurement control unit 114 measures the optical path length corresponding to the peak of the detected intensity and outputs the measurement result to the control unit 100. The thickness and the refractive index of the material of the new focus ring 5 are registered in the control unit 100. The control unit 100 may calculate the optical path length corresponding to the thickness and the refractive index of the material of the new focus ring 5 and measure the thickness of the focus ring 5 from the peak position of the light having the peak intensity near the calculated optical path length.

The measuring unit 110 and the elevation mechanism 120 are arranged at a plurality of positions in the circumferential direction of the focus ring 5. In the plasma processing apparatus 10 of the present embodiment, three pairs of the measuring unit 110 and the elevation mechanism 120 are provided. For example, the pairs of the measuring unit 110 and the elevation mechanism 120 are arranged at the second mounting table 7 at a regular interval in a circumferential direction of the second mounting table 7. The measuring unit 110 and the elevation mechanism 120 are disposed at the second mounting table at an interval of 120° in the circumferential direction of the second mounting table 7. Four or more pairs of the measuring unit 110 and the elevation mechanism 120 may be provided at the second mounting table 7. Further, the measuring unit 110 and the elevation mechanism 120 may be separately provided in the circumferential direction of the second mounting table 7.

The measurement control unit. 114 measures the thickness of the focus ring 5 at the positions of the measuring units 110 and outputs the measurement result to the control unit 100.

In the plasma processing apparatus 10, when the plasma processing is performed, the height of the plasma sheath is changed due to an error in the state of the wafer W, and the variation in the etching characteristics of each wafer W occurs.

In the plasma processing apparatus 10, when the plasma processing is performed, the focus ring 5 is consumed and the thickness of the focus ring 5 is reduced. When the thickness of the focus ring 5 is reduced, a height position of a plasma sheath above the focus ring 5 is deviated from a height position of a plasma sheath above the wafer W and, thus, the etching characteristics are changed.

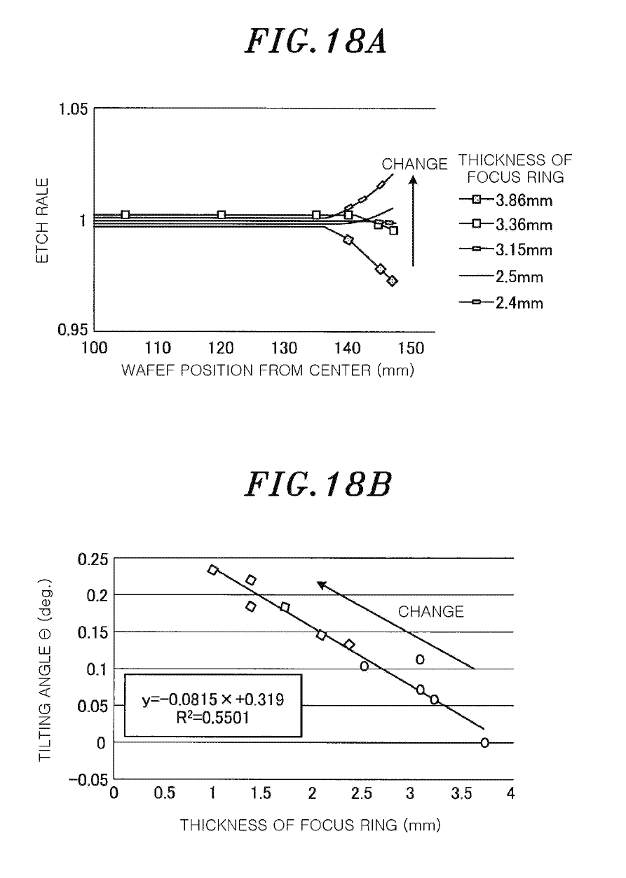

FIG. 18A shows an example of the relation between an etching rate and a thickness of the focus ring. FIG. 18A shows the etching rate measured by etching the wafer W while varying the thickness of the focus ring 5 and maintaining the height of the second mounting table 7 at a constant level. The size of the wafer W is set to 12 inches (diameter of 300 mm). FIG. 18A shows the changes in the etching rate with respect to the distance from the center of the wafer W for each thickness of the focus ring 5. The etching rate at the center of the wafer W is normalized as 1. As shown in FIG. 18A, the changes in the etching rate with respect to the changes in the thickness of the focus ring 5 are remarkable at the peripheral portion of the wafer W where the distance from the center of the wafer W is 135 mm or more.

FIG. 18B shows an example of the relation between the angle θ (tilting angle θ) of the etched hole and the thickness of the focus ring. FIG. 18B shows the angle θ of the hole measured in the case of performing etching while varying the thickness of the focus ring 5 and maintaining the height of the second mounting table 7 at a constant level. FIG. 18B shows changes in the angle θ of the hole at a position separated by 135 mm from the center of the wafer W for each thickness of the focus ring 5. As shown in FIG. 18B, the changes in the tilting angle θ with respect to the changes in the thickness of the focus ring 5 are remarkable at the peripheral portion of the wafer W.

Therefore, in the plasma processing apparatus 10 of the present embodiment, the elevation mechanism 120 is controlled in response to the state of the wafer W as the plasma processing target, and the thickness of the focus ring 5.

The acquisition unit 161a acquires the state information 163a of the wafer W as the plasma processing target. For example, the acquisition unit 161a reads out and acquires the state information 163a of the wafer W as the plasma processing target from the storage unit 163. The state information 163a includes data of the thickness of the wafer W at ea position in the circumferential direction of the wafer W which corresponds to the arrangement position of the measuring unit 110 and the elevation mechanism 120. In the present embodiment, the state information 163a is previously stored in the storage unit 163. However, when the state information. 163a is stored in another device, the acquisition unit 161a may acquire the state information 163a via a network.

The acquisition unit 161a acquires data of the height of the upper surface of the focus ring 5 by controlling the measurement control unit. 114 to measure the height of the upper surface of the focus ring 5 at a plurality of positions in the circumferential direction of the focus ring by using the respective measuring units 110. It preferable to measure the height of the focus ring 5 when a temperature in the processing chamber 1 is stabilized at a level at which plasma processing is performed. The height of the focus ring 5 may be measured multiple times at a regular interval during the etching of a single wafer W, or may be performed once for a single wafer W.

The plasma control unit 161b controls the elevation mechanism 120 based on the state of the wafer W indicated by the state information 163a acquired by the acquisition unit 161a such that the difference Δ_{wafer-FR} between the height of the interface of the plasma sheath above the wafer W and the height of the interface of the plasma sheath above the focus ring 5 is within the predetermined range.

For example, in the plasma processing apparatus 10, it is assumed that the standard height of the upper surface of the focus ring 5 during the plasma processing is determined. In that case, the plasma control unit 161b controls the elevation mechanism 120 to correct the height of the focus ring 5 to the standard height based on the height of the upper surface of the focus ring 5 which is measured by the measuring unit 110. Further, the plasma control unit 161b obtains the thickness of the wafer W as the processing target mounted on the first mounting table 2 from the state information 163a acquired by the acquisition unit 161a. The plasma control unit 161b reads out the correction value of the height of the focus ring 5 which corresponds to the thickness of the wafer W as the processing target from the correction information 163b. Then, the plasma control unit 161b controls the elevation mechanism 120 to vertically move the focus ring 5 to the corrected height during the plasma processing. For example, it is assumed that the correction value is a difference between the measured height of the focus ring 5 and the standard height of focus ring 5 during the plasma processing. The plasma control unit 161b controls the elevation mechanism 120 to correct the height of the focus ring 5 from the standard height by the correction value.

For example, when the positional relation between the height of the upper surface of the wafer W and the height of the upper surface of the focus ring 5 satisfies a predetermined distance, it is determined that the difference Δ_{wafer-FR} between the height of the interface of the plasma sheath above the wafer W and the height of the interface of the plasma sheath above the focus ring 5 is within the predetermined range. In that case, the plasma control unit 161b calculates the height of the focus ring 5 at which the positional relation satisfies the predetermined distance based on the state of the wafer W indicated by the state information 163a acquired the acquisition unit 161a and the height of the upper surface of the focus ring 5 which measured by the measuring unit 110. For example, the plasma control unit 161b calculates the height of the focus ring 5 at which the position relation between the upper surface of the wafer W and the upper surface of the focus ring 5 satisfies the predetermined distance at each position in the circumferential direction of the wafer W from the data of the thickness of the wafer W at each position in the circumferential direction of the wafer W. The plasma control unit 161b controls the elevation mechanisms 120 to vertically move the focus ring 5 by vertically moving the second mounting table 7 to the height calculated by the plasma control unit 161b.

Accordingly, in the plasma processing apparatus 10, the height of the upper surface of the wafer W becomes the same as the height of the upper surface of the focus ring 5, which makes it possible to suppress the variation in the etching characteristics of each wafer W.

As described above, in the plasma processing apparatus 10 according to the fifth embodiment, the elevation mechanism 120 is provided at a plurality of positions in the circumferential direction of the focus ring 5. The state information 163a includes measurement results obtained at a plurality of positions in the circumferential direction of the wafer W. The plasma control unit 161b controls the elevation mechanisms 120 based on the measurement results obtained at a plurality of positions indicated by the state information 163a such that the difference between the height of the plasma sheath above the wafer W and the height of the interface of the plasma sheath above the focus ring 5 is within the predetermined range for each position in the circumferential direction of the focus ring 5. Accordingly, the plasma processing apparatus 10 can suppress the variation in the etching characteristics in the circumferential direction of the wafer W.

Further, the plasma processing apparatus 10 according to the fifth embodiment includes the measuring units 110 for measuring the height of the upper surface of the focus ring 5. The plasma control unit 161b controls the plasma processing based on the state of the wafer W and the height of the upper surface of the focus ring 5 which is measured by the measurement unit 110 such that the difference between the height of the interface of the plasma sheath above the wafer W and the height of the interface of the plasma sheath above the focus ring 5 is within the predetermined range. Accordingly, the plasma processing apparatus 10 can suppress the variation in the etching characteristics of each wafer W even when the height of the upper surface of the focus ring 5 is changed due to the consumption by the plasma.

### Sixth Embodiment

Next, a sixth embodiment will be described. The plasma processing apparatus 10 according to the sixth embodiment has the same configuration as that of the plasma processing apparatus 10 according to the first embodiment, redundant description thereof will be omitted.

Although the outer diameter such as the diameter or the like of the wafer W is determined based on the standards as shown in 3, a certain error is allowed. In the plasma processing apparatus 10, the height position of the plasma sheath above the focus ring 5 is deviated from the height position of the plasma sheath above the wafer W due to the variation in the outer diameter of the wafer W and, thus, the etching characteristics are changed. Particularly, the peripheral portion of the wafer W is easily affected by the etching result including the variation in the etching rate and the shape abnormality such as tilting or the like due to the variation in the outer diameter of the wafer W.

The state information 163a according to the sixth embodiment includes the thickness and the outer diameter of the wafer W.

The correction value of the power supplied to the electromagnets 60a to 60c is stored, for each state of the wafer W, in the correction information 163b according to the sixth embodiment. For example, the amount of power supplied to the electromagnets 60a to 60c at which the difference Δ_{wafer-FR} between the height of the interface of the plasma sheath above the wafer W and the height of the interface of the plasma sheath above the focus ring 5 is within the predetermined range is experimentally measured for each thickness and each outer diameter of the wafer W. The correction value of the power supplied to the electromagnets 60a to 60c at which the difference Δ_{wafer-FR} is within the predetermined range is stored, for each thickness of the wafer W and each outer diameter of the wafer W, in the correction information 163b based on the measurement result. The correction value may be the amount of power at which the difference Δ_{wafer-FR} is within the predetermined range, or a difference between the measured amount of power and the standard amount of power supplied to the electromagnets 60a to 60c during the plasma processing. In the present embodiment, the correction value is the amount of power supplied to the electromagnets 60a to 60c.

The plasma control unit 161b controls the magnetic forces of the electromagnets 60a to 60c based on the state of the wafer W indicated by the state information 163a acquired by the acquisition unit 161a such that the difference Δ_{wafer-FR} between the height of the interface of the plasma sheath above the wafer W and the height of the interface of the plasma sheath above the focus ring 5 is within the predetermined range. For example, the plasma control unit 161b obtains the thickness and the outer diameter of the wafer W as the processing target mounted on the first mounting table 2 from the state information 163a acquired by the acquisition unit 161a. The plasma control unit 161b reads out the correction value of the power supplied to the electromagnets 60a to 60c which correspond to the thickness and the outer diameter of the wafer W as the processing target from the correction information 163b. Then, the plasma control unit 161b controls the power supply connected to the electromagnets 60a to 60c to supply the corrected power to the electromagnets 60a to 60c during the plasma processing.

Accordingly, in the plasma processing apparatus 10, the difference Δ_{wafer-FR} between the height of the interface of the plasma sheath above the wafer W and the height of the interface of the plasma sheath above the focus ring 5 is within the predetermined range, and the variation in the etching characteristics of each wafer W can be suppressed.

As described above, in the plasma processing apparatus 10 according to the sixth embodiment, the state of the wafer W includes both of the thickness of the wafer W and the outer diameter of the wafer W. As a result, the plasma processing apparatus 10 can suppress the variation in the etching characteristics of each wafer W even when there is an error in the thickness and the outer diameter for each wafer W.

While various embodiments have been described, various modifications can be made without being limited to the above-described embodiments. For example, although the above-described plasma processing apparatus 10 is the capacitive coupling type plasma processing apparatus 10, any plasma processing apparatus 10 may be employed. For example, the plasma processing apparatus 10 may be any plasma processing apparatus 10, such as the inductively coupled plasma processing apparatus 10 or the plasma processing apparatus 10 for exciting a gas by a surface wave such as a microwave.

In the above-described embodiments, the case in which the plasma state is changed by changing any one of the magnetic forces of the electromagnets 60, the power supplied to the electrode 9e, the power supplied to the central part 16i and the peripheral part 16j, or by vertical moving the focus ring 5 has been described as an example. However, the present disclosure is not limited thereto. The plasma state may be changed by changing the impedance. For example, the impedance of the second mounting table 7 can be changed. The plasma control unit 161b may control the impedance of the second mounting table 7 based on the state of the wafer W such that the difference Δ_{wafer-FR} between the height of the interface of the plasma sheath above the wafer W and the height of the interface of the plasma sheath above the focus ring 5 is within the predetermined range. For example, a ring-shaped space is formed in the second mounting table 7 in a vertical direction, and a ring-shaped conductor is provided in the space to be vertically movable by a conductor driving unit. The conductor is made of a conductive material such as aluminum or the like. Accordingly, the impedance of the second mounting table 7 can be changed by vertically moving the conductor by the conductor driving unit. The configuration of the second mounting table 7 may vary as long as the impedance thereof can be changed. The correction value of the impedance is stored, for each state of the wafer W, in the correction information 163b. For example, the height of the conductor at which the difference Δ_{wafer-FR} between the height of the interface of the plasma sheath above the wafer W and the height of the interface of the plasma sheath above the focus ring 5 is within the predetermined range is measured experimentally for each thickness of the wafer W. The correction value of the height of the conductor at which the difference Δ_{wafer-FR} is within the predetermined range is stored, for each thickness of the wafer W, in the correction information 163b based on the measurement result. The plasma control unit 161b obtains the thickness of the wafer W as the processing target mounted on the first mounting table 2 from the state information 163a acquired by the acquisition unit 161a. The plasma control unit 161b reads out the correction value of the height of the conductor which corresponds to the thickness of the wafer W as the processing target from the correction information 163b. Then, the plasma control unit 161b controls the conductor driving unit to correct the height of the conductor by the correction value during the plasma processing. Accordingly, in the plasma processing apparatus 10, the difference Δ_{wafer-FR} between the height of the interface of the plasma sheath above the wafer W and the height of the interface of the plasma sheath above the focus ring 5 is within the predetermined range, and the variation in the etching characteristics of each wafer W can be suppressed.

Further, in the above-described embodiments, the state of the wafer W includes the thickness and the outer diameter of the wafer W. However, the present disclosure is not limited thereto. For example, the state of the wafer W may be the shape of the end portion (wafer bevel portion) of the wafer. W, the type of the film formed or remaining on the backside of the wafer W, the film thickness, the eccentricity of the wafer W, the warpage of the wafer W, or the like. For example, various information used for correcting the conditions of the plasma processing are stored, for each state of the wafer W, in the correction information 163b. For example, the correction value of the power supplied to the electromagnets 60a to 60c at which the difference Δ_{wafer-FR} between the height of the interface of the plasma sheath above the wafer W and the height of the interface of the plasma sheath above the focus ring 5 is within the predetermined range is stored, for each shape of the end portion of the wafer W, in the correction information 163b. The plasma control unit 161b reads out the correction value of the power supplied to the electromagnets 60a to 60c which corresponds to the shape of the end portion of the wafer W as the processing target from the correction information 163b. Then, the plasma control unit 161b may control the power supply connected to the electromagnets 60a to 60c to supply the corrected power to the electromagnets 60a to 60c during the plasma processing.

Further, in the third embodiment, the case where a DC voltage is applied from the power supply 13 to the electrode 9e has been described as an example. However, the present disclosure is not limited thereto. For example, the power supply 13 may be an AC power supply. The plasma control unit 161b may control any one of a frequency, a voltage, and a power level of the AC power supplied from the power supply 13 to the electrode 9e based on the state of the wafer W such that the difference Δ_{wafer-FR} between the height of the interface of the plasma sheath above the wafer W and the height of the interface of the plasma sheath above the focus ring 5 is within the predetermined range.

Further, the above-described embodiments may be implemented in combination. For example, the first embodiment and the second embodiment may be combined. In that case, the magnetic forces of the electromagnets 60a to 60c and the DC voltage applied to the electrode 9e may be controlled such that the difference Δ_{wafer-FR} between the height of the interface of the plasma sheath above the wafer W and the height of the interface of the plasma sheath above the focus ring 5 is within the predetermined range. For example, the elevation mechanisms 120 of the fifth embodiment are added to the plasma processing apparatus 10 of the first embodiment to the third embodiment, and the upper surface of the focus ring 5 is corrected to the standard height. Then, the plasma processing may be controlled based on the state of the wafer W such that the difference Δ_{wafer-FR} between the height of the interface of the plasma sheath above the wafer W and the height of the interface of the plasma sheath above the focus ring 5 is within the predetermined range.

In the fifth embodiment and the sixth embodiment described above, the case in which the focus ring 5 is vertically moved by vertically moving the second mounting table 7 by the elevation mechanism 120 has been described as an example. However, the present disclosure is not limited thereto. For example, only the focus ring 5 can be vertically moved by pins or the like perpetrating through the second mounting table 7.

In the sixth embodiment, the case in which the focus ring 5 is vertically moved depending on both of the thickness of the wafer W and the outer diameter of the wafer W. However, the present disclosure is not limited thereto. For example, the focus ring 5 may be vertically moved depending on only the outer diameter of the wafer W.

In the plasma processing apparatus 10, when multiple types of plasma etching processes are performed on a single wafer W, it is possible to vertically move the second mounting table 7 and change the position of the focus ring with respect to the wafer W in each plasma etching process so that the variation in etching characteristics of each plasma process can be suppressed.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A plasma processing apparatus comprising:
a mounting table on which a target object as a plasma processing target is mounted;
a focus ring disposed to surround the target object;
an acquisition unit configured to acquire state information indicating a measured state of the target object; and
a plasma control unit configured to control plasma processing based on the state of the target object indicated by the state information acquired by the acquisition unit such that a difference between a height of an interface of a plasma sheath above the target object and a height of an interface of a plasma sheath above the focus ring is within a predetermined range.

2. The plasma processing apparatus of claim 1, further comprising:
one or more electromagnets arranged in parallel with at least one of the target object and the focus ring,
wherein the plasma control unit controls magnetic forces of the electromagnets by controlling power supplied to the electromagnets based on the state of the target object such that the difference between the height of the interface of the plasma sheath above the target object and the height of the interface of the plasma sheath above the focus ring is within the predetermined range.

3. The plasma processing apparatus of claim 1, further comprising:
an electrode, provided on a mounting surface on which the focus ring is mounted, to which a DC voltage is applied,
wherein the plasma control unit controls the DC voltage applied to the electrode based on the state of the target object such that the difference between the height of the interface of the plasma sheath above the target object and the height of the interface of the plasma sheath above the focus ring is within the predetermined range.

4. The plasma processing apparatus of claim 1, further comprising:
an electrode, provided on a mounting surface on which the focus ring is mounted, to which an AC voltage is applied,
wherein the plasma control unit controls the AC voltage applied to the electrode based on the state of the target object such that the difference between the height of the interface of the plasma sheath above the target object and the height of the interface of the plasma sheath above the focus ring is within the predetermined range.

5. The plasma processing apparatus of claim 1, further comprising:
an additional mounting table on which the focus ring is mounted and having a variable impedance,
wherein the plasma control unit controls the impedance of the additional mounting table based on the state of the target object such that the difference between the height of the interface of the plasma sheath above the target object and the height of the interface of the plasma sheath above the focus ring is within the predetermined range.

6. The plasma processing apparatus of claim 1, further comprising:
a gas supply unit including electrodes that are arranged to face the target object and the focus ring in parallel with at least one of the target object and the focus ring, and configured to inject a processing gas,
wherein the plasma controller controls power supplied to the electrode based on the state of the target object such that the difference between the height of the interface of the plasma sheath above the target object and the height of the interface of the plasma sheath above the focus ring is within the predetermined range.

7. The plasma processing apparatus of claim 1, further comprising:
one or more elevation mechanisms configured to vertically move the focus ring,
wherein the plasma controller controls the elevation mechanism such that a difference between the height of the interface of the plasma sheath above the target object and the height of the interface of the plasma sheath above the focus ring is within the predetermined range based on the state of the target object.

8. The plasma processing apparatus of claim 7, wherein the elevation mechanisms are provided at a plurality of positions in a circumferential direction of the focus ring,
the state information includes state measurement results obtained at a plurality of positions in the circumferential direction of the target object, and
the plasma control unit controls the elevation mechanisms based on the state measurement results obtained at the plurality of positions indicated by the state information such that the difference between the height of the interface of the plasma sheath above the target object and the height of the interface of the plasma sheath above the focus ring is within the predetermined range for each of the plurality of positions in the circumferential direction of the focus ring.

9. The plasma processing apparatus of claim 1, further comprising:
a measurement unit configured to measure a height of an upper surface of the focus ring,
wherein the plasma control unit controls the plasma processing based on the state of the target object and the height of the upper surface of the focus ring which is measured by the measurement unit such that the difference between the height of the interface of the plasma sheath above the target object and the height of the interface of the plasma sheath above the focus ring is within the predetermined range.

10. The plasma processing apparatus of claim 8, further comprising:
a measurement unit configured to measure a height of an upper surface of the focus ring,
wherein the plasma control unit controls the plasma processing based on the state of the target object and the height of the upper surface of the focus ring which is measured by the measurement unit such that the difference between the height of the interface of the plasma sheath above the target object and the height of the interface of the plasma sheath above the focus ring is within the predetermined range.

11. The plasma processing apparatus of claim 1, wherein the state of the target object includes one or both of a thickness of the target object and an outer diameter of the target object.

12. The plasma processing apparatus of claim 8, wherein the state of the target object includes one or both of a thickness of the target object and an outer diameter of the target object.

13. The plasma processing apparatus of claim 10, wherein the state of the target object includes one or both of a thickness of the target object and an outer diameter of the target object.

14. The plasma processing apparatus of claim 13, wherein the state of the target object includes one or both of a thickness of the target object and an outer diameter of the target object.

15. A plasma control method comprising:
acquiring state information indicating a measured state of a target object as a plasma processing target; and
controlling plasma processing based on the state of the target object indicated by the acquired state information such that a difference between a height of a plasma sheath above the target object mounted on a mounting table and a height of an interface of a plasma sheath above a focus ring that surrounds the target object is within a predetermined range.

16. A computer-readable storage medium including computer executable instructions, wherein the instructions, when executed by a processor, cause the processor to perform a plasma control method including:
acquiring state information indicating a measured state of a target object as a plasma processing target; and
controlling plasma processing based on the state of the target object indicated by the acquired state information such that a difference between a height of an interface of a plasma sheath above the target object mounted on a mounting table and a height of an interface of a plasma sheath above a focus ring is within a predetermined range.
